(19) United States
(12) Patent Application Publication
(10) Pub. No.: US 2009/0072243 A1
(43) Pub. Date: Mar. 19, 2009

(54) Compound semiconductor device and method for fabricating compound semiconductor

(75) Inventors: Jun Suda, Kyoto (JP); Tsunenobu Kimoto, Kyoto (JP)

Correspondence Address: REED SMITH LLP, 3110 FAIRVIEW PARK DRIVE, SUITE 1400, FALLS CHURCH, VA, 22042, US

(73) Assignee: Kyoto University

(21) Appl. No.: 11/918,733

(22) PCT Filed: Apr. 5, 2006
(86) PCT No.: PCT/JP2006/307205

§ 371 Date: Oct. 18, 2007

(30) Foreign Application Priority Data
Apr. 18, 2005 (JP) 2005-119971

(51) Int. Cl. H01L 29/24; H01L 21/30

(52) U.S. Cl. 257/77; 438/459; 257/E29.104

(57) ABSTRACT

In the present invention, a technology for causing arbitrary polarity, crystal face and crystal orientation to exist mixedly in a plane on the surface of a SiC substrate, and for forming a SiC layer or a group III-nitride or group II-oxide layer on the surface, is provided. A first SiC substrate 41 having (0001) face and a second SiC substrate 44 having (000-1) face are prepared. An oxide film 43 is formed on the surfaces of the SiC substrates 41 and 44 by subjecting them to an oxidation treatment, and then the two SiC substrates are fusion-bonded so that the rear surface of the second SiC substrate and the surface of the first SiC substrate are brought into contact with each other. Subsequently, a part corresponding to the second SiC substrate 44 is made thin (44a). Subsequently, a thin layer 44a of the second SiC substrate is removed in accordance with required periodic reversal to be processed in stripes by using a lithography technology and reactive ion etching technology. This enables a substrate to be produced, where the (0001) face and the (000-1) face of SiC appear alternately on the surface (a region denoted by reference numeral 441 and a region denoted by 44b/43a). On the substrate thus produced, an AlGaN layer 45a to be a first cladding layer, a GaN layer 46a to be an optical guide layer, and an AlGaN layer 45c to be a second cladding layer, are grown. The group III-nitrides grow while inheriting the face orientation of SiC exposed on the surface and thereby a structure where crystal axes are spatially-periodically reversed can be attained. In other words, a second laminated structure 45a/46b/47a is formed on the first laminated structure 43a/44b, and a third laminated structure 45b/46b/47b is formed on a region where the first laminated structure 43a/44b is not formed. Finally, a stripe structure for realizing light confinement in the lateral direction, i.e. the in-plane direction of the substrate, is formed by using a known processing technology including lithography and reactive ion etching, thus completing a non-linear optical element.

### TECHNICAL FIELD

The present invention relates to a compound semiconductor device such as SiC, a group III-nitride, or a group II-oxide, more specifically, relates to a fundamental technology for controlling polarity, crystal face, and crystal orientation of a SiC semiconductor, and a semiconductor device based on the same.

### BACKGROUND ART

SiC has a very high thermal conductivity, and an electrically conductive substrate and an electrically insulating substrate can also be obtained from SiC. SiC is characterized by having lattice constant and thermal expansion coefficient relatively nearer to those of a group III-nitride such as AlN or GaN and a group II-oxide such as ZnO, and further, similar to those nitride and oxide, being a polar hexagonal crystal or a polar cubic crystal. Between SiC and the group III-nitride, there is a relationship in that bonds between Si and N and bonds between C and a group III-metal are strong, and a property in that the polarity of a grown group III-nitride can be easily controlled. In other words, in a SiC (0001) Si polar face in which Si bond perpendicularly extends with respect to the interface between them, Si and N bond together in an interface of growth, as a result, the grown group III-nitride has a structure in which bond of group III-atoms perpendicularly extends, namely a group III-polar face. Similarly, between SiC and the group II-oxide, there is a similar relationship, that is, a property in that the polarity of the group II-oxide is determined by the polarity of SiC.

In recent years, technologies and developments for crystal growth of high quality AlN and GaN-based group III-nitrides onto a SiC substrate have been developed, and a device having a group III-nitride as a device active layer, such as a light emitting diode of green light to ultraviolet rays, a laser diode, and a high frequency power transistor, is going to be brought to realization. In fabrication of such a device, it is required for the polarity and the crystal orientation of the group III-nitride crystal to be one uniform polarity and orientation over the entire substrate. That the polarity of the group III-nitride crystal is fixed to one by the polarity of the SiC substrate, is a very effective matter in meanings, such as improvement in fabrication yield, and prevention of the device performance from being degraded due to inclusion of micro polarity reversal regions.

Meanwhile, for some kind of device, or an integrated device in which a plurality of elements are integrated, it is necessary in manufacturing, to artificially introduce regions having reverse polarities, and regions having different crystal orientations in a substrate surface of the device. For example, in a GaAs-based compound semiconductor, a quasi phase matched wavelength conversion element has been produced by using a polarity reversal technology (refer to, for example, Non-Patent Document 1).

Non-Patent Document 1: L. A. Eyres, et al., “All-epitaxial fabrication of thick, orientation-patterned GaAs films for nonlinear optical frequency conver Sion”, Appl. Phys. Letts. Vol. 79, No. 7 p. 904-906,(2001).

### DISCLOSURE OF THE INVENTION

### Problems to be Solved by the Invention

As a substrate of the group III-nitrides or the group II-oxides, sapphire (Al₂O₃) is used as well as SiC. Since sapphire is a crystal without polarity, the polarity of the group III-nitride or the group II-oxide grown thereon, is not determined by the crystal orientation of the sapphire substrate, but the polarity of a grown layer is controlled by growth conditions and substrate processing conditions. This is a demerit in meaning of uniformity and repeatability of the polarity mentioned-above; however, when a structure having mixed polarities is intended to be produced, it is a merit conversely, because such a structure can be achieved by patterning the surface of the substrate, and partially subjecting the surface of the substrate to different growth conditions and substrate processing conditions. Practically, an in-plane polarity reversal structure of a group III-nitride is achieved on the sapphire substrate by such a method. On the other hand, although the SiC substrate has advantages over the sapphire with respect to a lattice matching property, control in thermal conductivity and in electrical conductivity, and the like, with regard to polarity, it has been very difficult to produce the polarity reversal structure, because the polarity of the grown layer has been determined by the polarity of the SiC substrate.

An object of the present invention is to provide a technology for causing any polarities, crystal faces, and crystal orientations to coexist in a plane on a surface of a SiC substrate, and for forming a SiC layer, or a layer of a group III-nitride or a group II-oxide on the surface. Moreover, another object is also to provide a technology for bonding SiCs each having a different polarity, crystal face, and crystal orientation, for the purpose of the above object.

### Means for Solving the Problems

According to one aspect of the present invention, a method for fabricating a semiconductor device is provided, which is characterized by including: a step for preparing a first SiC substrate having a first crystal face and a second SiC substrate having a second crystal face; a step for bonding the first SiC substrate and the second SiC substrate so that a rear surface of the first crystal face and the second crystal face are brought into contact with each other; and a step for completely removing the first SiC substrate at a partial region in a plane thereof and for exposing the second crystal face being a surface of the second SiC substrate upon a surface of a substrate after bonded, on the surface of the substrate a structure in which the first crystal face of the first SiC substrate and the second crystal face of the second SiC substrate coexist on the surface of the substrate, being formed so that two kinds of crystal faces of the first crystal face and second crystal face appearing on the surface of the substrate are different from each other in at least one of crystal face orientation and in-plane crystal orientation.

Moreover, a method for fabricating a semiconductor device is provided, which is characterized by including: a step for preparing a first SiC substrate having a first crystal face and a second SiC substrate having a second crystal face; a step for ion-implanting hydrogen or rare gas into a rear surface of the first crystal face of the first SiC substrate so that the concentration thereof becomes maximum at a certain depth from the rear surface; a step for fusion bonding the first SiC substrate and the second SiC substrate by arranging the substrates so that the rear surface of the first crystal face and the second crystal face are brought into contact with each other and by subjecting the substrates to a thermal treatment, and for causing the substrates to peel automatically when the implanted atom concentration is approximately maximum, and a step for completely removing the first SiC substrate in a partial region on the surface of the second SiC substrate, which is kept bonded to the second SiC substrate and left on a surface of the second SiC as a thin film after peeling, and for exposing the second crystal face being the surface of the second SiC substrate upon a surface of a substrate after bonded, on the surface of the substrate, a structure in which the first crystal face of the first SiC substrate and the second crystal face of the second SiC substrate coexist on the surface of the substrate, being formed so that two kinds of crystal faces of the first crystal face and second crystal face appearing on the surface of the substrate are different from each other in at least one of crystal face orientation and in-plane crystal orientation.

As mentioned above, since two kinds of surfaces appearing on the surface of the substrate can be caused to differ from each other in at least one of crystal face orientation and in-plane crystal orientation, application to various devices is possible.

According to another aspect of the present invention, a monolithic device is provided; where, as a first SiC substrate and a second SiC substrate, any one of SiC substrates having crystal structures of 3C, 4H, 6H, and 15R is used; as a first crystal face, a (0001) Si face or a (000-1) C face (in a case of the 3C structure, a {111} Si face or a {-1-1-1} C face), or a crystal face at an angle being equal to or smaller than 30 degrees from these faces, is used; and as a second crystal face, a {1-100} face, or a {11-20} face (in a case of the 3C structure, a {100} face or a {110} face, or a {1-10} face), or a crystal face at an angle being equal to or smaller than 15 degrees from these faces, is used; and, a transistor or diode using SiC or a III-V-group or II-VI-group semiconductor is formed on the first crystal face, and a light emitting diode, laser diode, or photodiode, using a III-V-group or II-VI-group semiconductor is formed on the second crystal face.

According to another aspect of the present invention, a method for fabricating a piezoelectric device, a sensor device, or a micro-machine is provided, which includes: a step for preparing a first SiC substrate and a second SiC substrate in both of which a high concentration impurity region having a second conductivity-type being different from a first conductivity-type is locally formed in a semi-insulating or first conductivity-type substrate having a SiC (0001) Si face or a SiC (000-1) C face, or a crystal face at an angle being equal to or smaller than 10 degrees from the faces; a step for bonding the first substrate and the second substrate so that surfaces thereof are brought into contact with each other; a step for exposing a surface of the high concentration impurity region by selectively removing the intermediate layer and the SiC layer of the first substrate; and a step for forming a film of a group III-nitride or group II-oxide, and for removing the deposited films of respective partial regions of the first substrate and second substrate, and for forming electrodes on the removed regions and the group III-nitride film or group II-oxide film, respectively.

Moreover, a non-linear optical element is provided, including: a SiC substrate on which a first crystal face and a second crystal face being different from the first crystal face are formed; and a stripe structure where a first laminated structure formed on the SiC substrate, which has a first lower clad formed on the first crystal face and inheriting properties of the first crystal face, a first active layer, and a first upper cladding layer, and a second laminated structure which has a second lower clad formed on the second crystal face and inheriting properties of the second crystal face, a second active layer, and a second upper cladding layer, are arranged alternately in an in-plane direction of the substrate.

Further, a semiconductor device is provided, including: a SiC substrate on which a first crystal face and a second crystal face being different from the first crystal face are formed; and a structure formed on the SiC substrate, of both a first field effect transistor using, as a channel layer, a first layer which is formed on the first crystal face and inheriting properties of the first crystal face, and a second field effect transistor using, as a channel layer, a second layer which is formed on the second crystal face and inheriting properties of the second crystal face.

### Advantages of the Invention

According to the present invention, a structure having different polar faces, crystal faces, or crystal orientations on SiC can be produced. By using this as a starting point (template) of production of various devices and functional materials, a functional material and a non-linear optical device which have a large non-linear optical effect; a trench-mesa structure having a high aspect ratio formed by using a selective etching of polarity; a micro-machine; an integrated circuit of transistors each having a different threshold voltage; and an integrated device of a high performance transistor and a high performance light emitting device, can be achieved. Moreover, there are advantages in that utilization of the bonding technology enables any structure to be embedded in the bonded interface, and that the process for fabricating a semiconductor device including two or more elements, and integration thereof become easy.

### BRIEF DESCRIPTION OF THE DRAWINGS

FIGS. 1(A) to 1(C) are views illustrating a method for fabricating a SiC semiconductor crystal according to a first embodiment of the present invention, in order of main process steps;

FIGS. 2(A) to 2(D) are views illustrating the method for fabricating the SiC semiconductor crystal according to the present embodiment, in order of main process steps, and following FIGS. 1(A) to 1(C);

FIGS. 3(A) to 3(D) are views illustrating the method for fabricating the SiC semiconductor crystal according to the present embodiment, in order of main process steps, and following FIGS. 2(A) to 2(D);

FIGS. 4(E) and 4(D) are views illustrating a method for fabricating a SiC semiconductor crystal according to a modified example of the first embodiment of the present invention, and illustrating a lamination step using combination of a Si polar face and a non-polar face (1120) or (1100);

FIG. 5 is a view illustrating the method for fabricating the SiC semiconductor crystal according to the modified example of the present embodiment, and following FIGS. 4(E) and 4(D);

FIGS. 6(A) to 6(G) are views illustrating a method for fabricating a semiconductor device according to a second embodiment of the present invention, and illustrating an example of a case where Smart Cut technology is used;

The method for fabricating a semiconductor device according to a third embodiment of the present invention will be described with reference to drawings. FIGS. 7(A) and 7(B) are views illustrating a step for performing lamination etc. after forming specific embedded structures in SiC substrates themselves in advance;

FIGS. 8(C) and 8(D) are views illustrating the method for fabricating the semiconductor device according to the present embodiment, and following FIGS. 7(A) and 7(B);

FIGS. 9(A) to 9(D) are views illustrating a method for fabricating a semiconductor device according to a fourth embodiment of the present invention;

FIGS. 10(A) to 10(E) are views illustrating a configuration with regard to a polar face of SiC;

FIGS. 11(A) and 11(B) are views illustrating a method for fabricating a non-linear optical element according to a second specific example of the present embodiment;

FIGS. 12(A) to 12(G) are views illustrating one example of the method for fabricating the non-linear optical element;

FIGS. 13(A) and 13(B) are views with regard to a polar face of SiC;

FIGS. 14(A) to 14(H) are views illustrating a method for fabricating the non-linear optical element according to another embodiment different from the method for fabricating the non-linear optical element illustrated in FIGS. 11(A) and 11(B), and 12(A) to 12(G);

FIG. 15(A) is a perspective view illustrating one configuration example of a non-linear optical element having a periodic polarization reversal structure;

FIG. 15(B) is a cross-sectional view along the optical waveguide, illustrating one configuration example of the non-linear optical element having the periodic polarization reversal structure; and

FIGS. 16(A) to 16(G) are views illustrating one example of a method for fabricating the structure illustrated in FIGS. 15(A) and 15(B).

### DESCRIPTION OF SYMBOLS

1 . . . SiC substrate, 1a . . . SiC substrate (for polarity reversal), 3a . . . (Upper surface), 3b . . . (Lower surface), 3C . . . (Side surface), 17 . . . GaN layer having an N polar face, 17a . . . GaN having a GaN polar face.

### BEST MODE FOR CARRYING OUT THE INVENTION

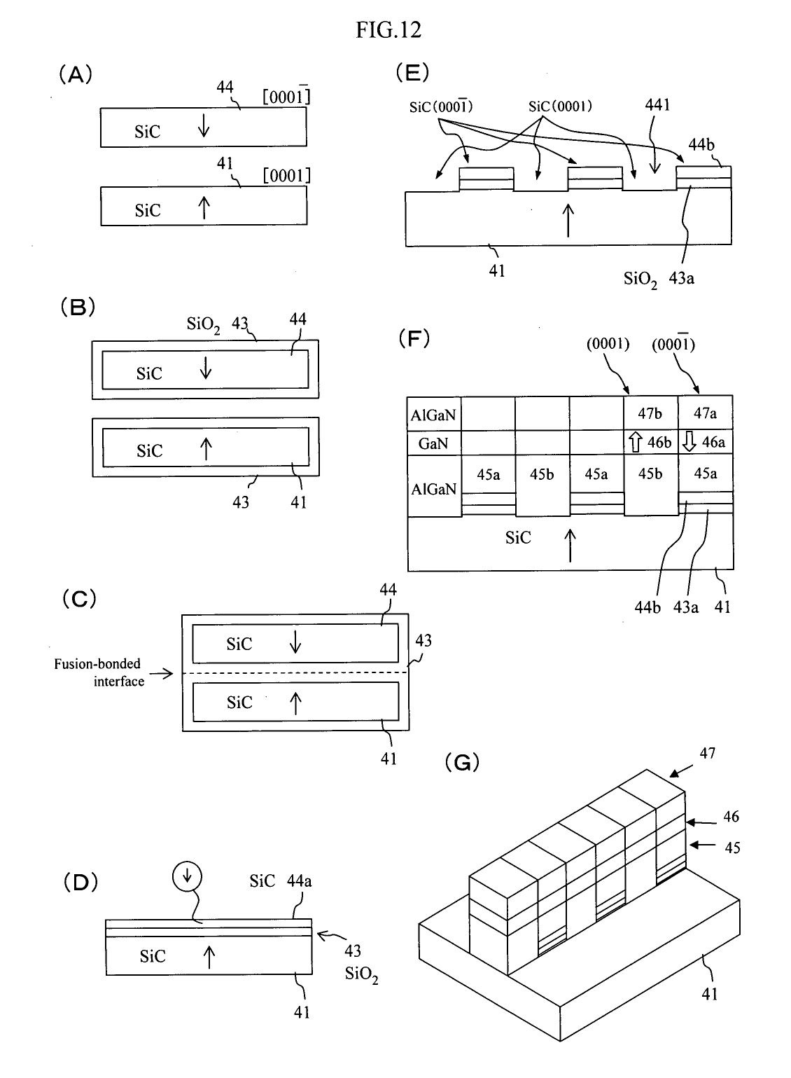

Hereinafter, a SiC semiconductor device according to an embodiment of the present invention and a method for fabricating the semiconductor device will be described with reference to drawings. FIGS. 13(A) and 13(B) are views regarding a polarity of SiC. As illustrated in FIG. 13(A), the polarity of a crystal is defined by whose bond of a Si atom (indicated by a white round mark) and a C atom (indicated by a black round mark) is extending from the crystal surface toward a direction perpendicular to the surface. In a structure illustrated in FIG. 13(A), the bond of Si is perpendicularly extending from the crystal surface, and thereby, this situation is referred to as a Si polarity, and the plane is referred to as a (0001) face or more explicitly as a (0001) Si face (in a case of 3C-SiC, a {111} face or a {111} Si face). On the other hand, in a structure illustrated in FIG. 13(B), the bond of C is perpendicularly extending from the crystal surface, and thereby, this situation is referred to as a C polarity, and the plane is referred to as a (000-1) face or more explicitly as a (000-1) C face. In a plane having offset angles from the (0001) face and a (000-1) face which are reverse planes with each other by 180 degrees, both of the bonds of Si and C appear; however, for convenience' sake, they are called a Si polarity or a C polarity depending on whether their angles crossing 90 degrees. Moreover, a {11-20} face and a {1-100} face, which locate on just 90 degrees, and planes between them, are referred to as a non-polar face without polarity.

As mentioned-above, since bonds between Si and N, and between C and a group III-metal are strong, if a group III-nitride is grown on SiC, on a SiC (0001) Si polarity, Si and N bond together. As a result, the grown group III-nitride will have a structure where the bond of the group III-atom extends perpendicularly, that is, a group III-polar face.

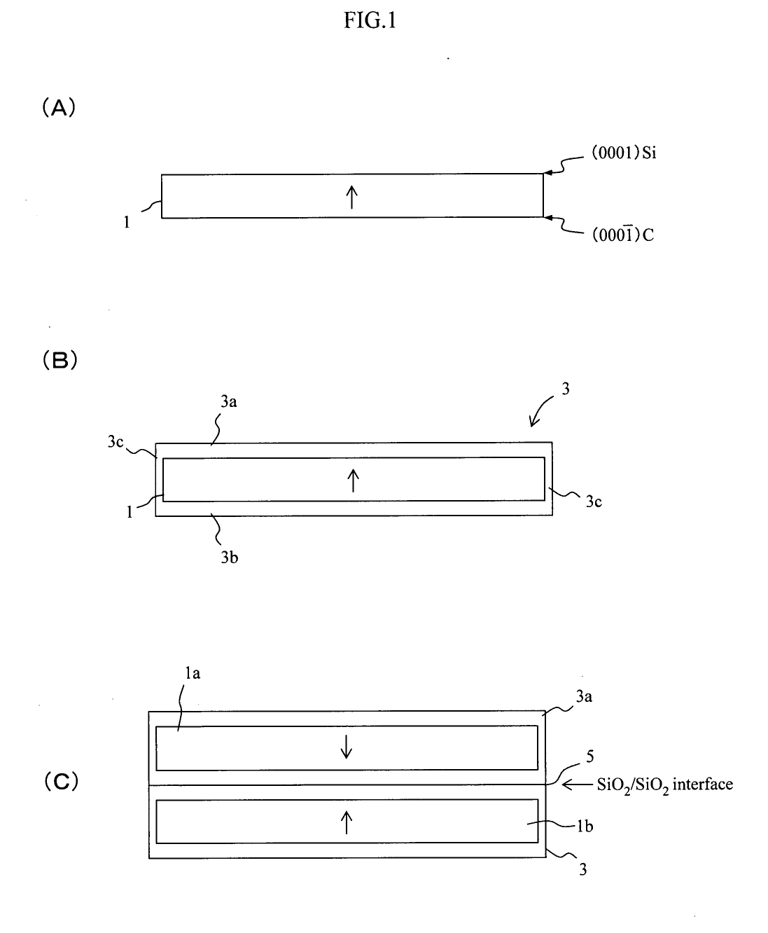

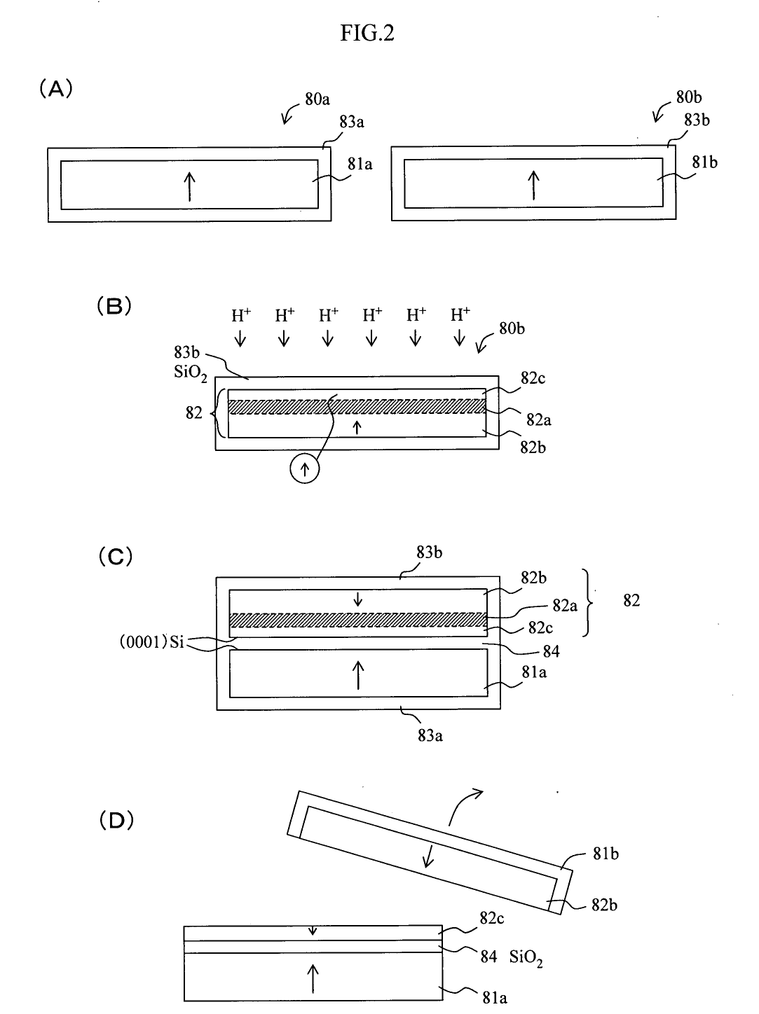

First before describing the embodiment of the present invention in detail, two principles of first and second technologies for fabricating a semiconductor of the present invention will be described with reference to FIGS. 1 and 2.

FIGS. 1(A) to 1(C) are schematic views illustrating a first technology for fabricating a semiconductor device of the present invention. Two SiC (0001) substrates 1 illustrated in FIG. 1(A) (in FIG. 1(A), only one substrate is illustrated) are prepared, and, if necessary, subjected to a surface treatment for cleaning the surface. As described with reference to FIG. 13, one surface of the SiC substrate 1 becomes a (0001) Si polar face where a bond extends from a Si atom perpendicularly (the direction indicated by an arrow is denoted as a direction of a surface having a Si polar face), and the other surface (rear surface) becomes a (000-1) C polar face (the opposite one to the direction indicated by an arrow is denoted as a direction of a surface having a C polar face).

In this state, as illustrated in FIG. 1(B), by being oxidized, for example, at a temperature of 1150° C. for two hours under a normal pressure oxygen atmosphere, the entire surfaces of the substrate, that is, a top surface side 3a, a rear surface side 3b, and a side surface side 3c, have an oxide film of SiO₂ formed thereon. Next, as illustrated in FIG. 1(C), two substrates 1a and 1b each having the oxide film formed thereon are laminated together in an arrangement where their (0001) Si faces face each other (directions indicated by their arrows face each other). After laminating the substrates 1a and 1b, by subjecting them to a heat treatment, for example, at a temperature of 800° C. to 1000° C. for several hours, a strong wafer fusion-bonding can be performed. This step is based on physical and chemical phenomena similar to those of Direct Bonding (fusion-bonding of Si wafers through SiO₂) used for production of SOI (Silicon on Insulator). The thickness of the oxide film is set appropriately by considering fusion-bonding conditions. In some cases, fusion-bonding conditions for forming a very thin oxide film or for forming an oxide film only on one substrate intentionally, may be used.

Based on the above-mentioned step, as illustrated in FIG. 1(C), a substrate having an arrangement where (0001) Si faces are facing each other (referred to as a polarity reversal substrate) can be produced. The large difference between the above-mentioned step and Direct Bonding step of Si is as follows. That is, since SiC has heat resistance higher than that of Si, it is also possible to use a fusion-bonding temperature being equal to or greater than 1000° C., for example, a temperature being equal to or greater than the glass transition temperature of SiO₂, such as 1450° C. If such a high temperature is used, even if the flatness of the planes to be fusion-bonded before fusion-bonding is not good to some extent, the fluidity of SiO₂ enables good fusion-bonding to be achieved. As described below, when various kinds of device structures are produced on the fusion-bonding face of SiC in advance, since it is difficult to completely flatten the SiC fusion-bonding face, the fusion-bonding method of substrates under such a high temperature becomes very effective. In order to utilize the advantage of such a high temperature fusion-bonding, it is desirable for the thickness of the oxide film to be thick to some extent.

FIGS. 2(A) to 2(D) are schematic views illustrating a second technology for fabricating a semiconductor according to the present invention. The second technology for fabricating a semiconductor according to the present invention is a technology utilizing a smart cut technology. As illustrated in FIG. 2(A), first, two SiC (0001) substrates 81a and 81b are prepared. Subsequently, oxide films 83a and 83b are formed on wafer surfaces of Si faces, respectively (this technology can be achieved even if all of the Si faces are replaced by C faces as a reverse pattern of crystal face with respect to the technology described below). For example, by being subjected to an oxidation treatment at a temperature of 1150° C. for about two hours under an oxygen normal pressure atmosphere, and thereby forming an oxide film on the surface, structures each denoted by reference numerals 80a (including the substrate 81a) and 80b (including the substrate 81b) are formed. Subsequently, as illustrated in FIG. 2(B), H+ions are implanted into a (0001) Si polar face side through the oxide film 83b so as to have a peak at a shallow position in the depth direction near one surface of the one substrate 81b (FIG. 1(B)), and a SiC insulating layer 82a is formed in a region in a certain thickness direction in a SiC layer 82. This causes a structure 82 having different concentrations of H⁺ ions in the thickness direction, to be formed. At that time, based on the relationship between the ion-implanted depth and concentration of H⁺ ions by ion implantation, the neighborhood of the surface becomes a region 82c where the concentration of H⁺ ions is low.

Subsequently, as illustrated in FIG. 2(C), the one substrate structure 82 (81b in FIG. 2(B)) and the other substrate 81a are laminated by being arranged through an oxide film 84 (83a and 83b) in a direction where (0001) Si polar faces of both substrates 81a and 82 face each other. After that, by subjecting the substrates to a thermal treatment at a temperature of 800° C. to 1000° C. for several hours, strong wafer fusion-bonding is achieved. At that time, as illustrated in FIG. 2(D), a wafer (the thick region of 81b) peels automatically at a part (a position in the depth direction) 82a, where H⁺ ions have been implanted. This enables the thin SiC layer 82c to be left on the substrate 81a, with the oxide film 84 being sandwiched between them. A polarity reversal substrate similar to that in FIG. 1(C) can also be formed.

According to the second method for fabricating the semiconductor device of the present invention, since an isolating position (depth) can be adjusted and set by the implantation energy of H⁺ ion implantation, there is an advantage in that an additional step of thinning and flattening is not necessary, or even if the additional step of thinning and flattening is performed, polishing amount can be remarkably reduced. Accordingly, substrate materials (powder etc.) required to be discarded by polishing can also be as little as possible. In particular, in a fabricating process using a SiC substrate requiring large cost and electric power for producing a bulk, the merit is very large.

In addition, it is also possible to thin and flatten the first SiC substrate 1a or the substrate 81a by polishing the entire surface thereof after performing the first and second production processes, or it is also possible to utilize a substrate before fusion-bonding, which is thinned to be equal to or smaller than 50 microns in advance, as the first SiC substrate 1a or the substrate 81a.

Each polarity reversal substrate completed by the above-mentioned steps has a structure of SiC(1a)/SiO₂(5)/SiC (1b) in FIG. 1(C) or SiC(82c)/SiO₂(84)/SiC (83a) in FIG. 1(D), and by using these substrates characterized in that SiC (1a or 82c) and SiC (1b or 83a) are different from each other in polarity of SiC seen from the substrate surface, as a starting substrate (template), various devices can be produced as described below.

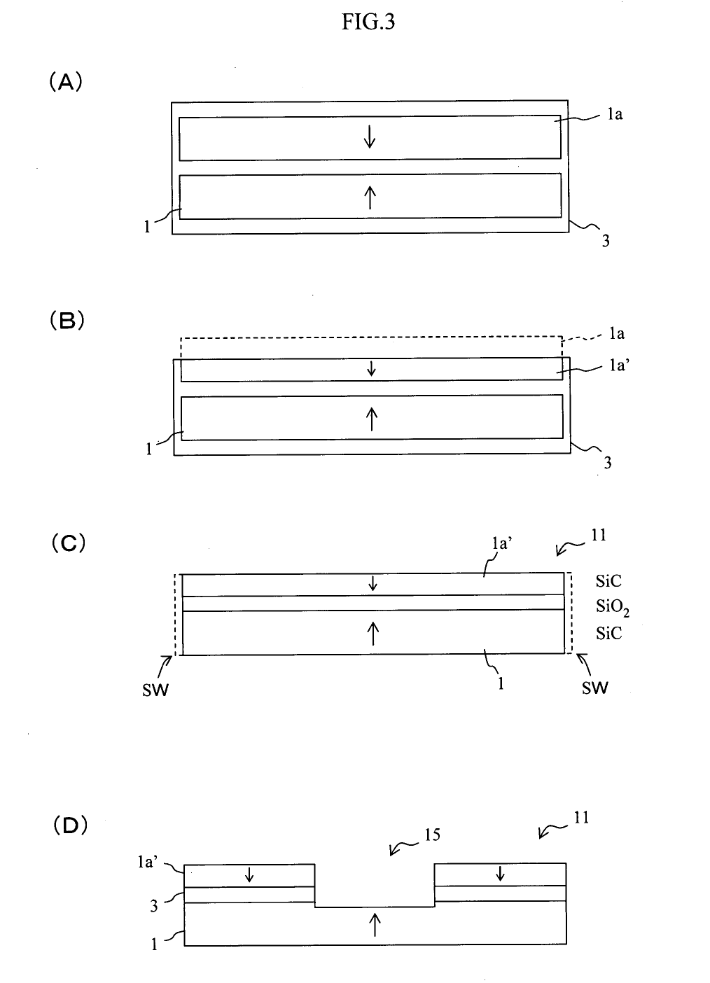

Hereinafter, using the first crystal technology as an example, a semiconductor fabricating technology according to a first embodiment of the present invention will be described with reference to drawings. FIGS. 3(A) to 3(D) are views illustrating steps following to the step illustrated in FIG. 1(C) (the SiO₂/SiO₂ interface is eliminated). First, as illustrated in FIG. 3(A), by forming Si—O—Si bond in the SiO₂ interface (5: FIG. 1(C)), a state is formed, where SiO₂ surfaces are strongly fusion-bonded to each other. Next, as illustrated in FIG. 3(B), using, for example, such as a CMP (Chemical Mechanical Polishing) method, the substrate 1a is polished from the surface side (top surface side) in FIG. 3(A), and thereby the substrate 1a is caused to be a thin film 1a′. At that time, a side wall SW is also removed simultaneously. This causes a polarity reversal template to be completed (FIG. 3(C)). The polarity-reversed template structure illustrated in FIG. 3(C) is a laminated structure of SiC/SiO₂/SiC, and characterized in that SiC 1 and SiC 1a′ are different from each other in polarity, with SiO₂ being sandwiched between them. If the polarities are not paid attention, the structure seems superficially to be the same as the structure of SiConInsulator (SiCoI) when SiC is used as a holding substrate, however, if the polarities are paid attention, the structure has an object to be completely different from that of the structure of SiConInsulator. In other words, in a general SiCoI, a base substrate is used merely as the holding substrate, and there is no special object in the orientation of the surface thereof. Moreover, the SiCoI has not the concept specific to the present invention, that the holding substrate is intentionally exposed, and, as described below, a thin film is formed on the surface thereof.

First, a photomask which is not illustrated in figures and opens a region where the Si polar face is to be maintained, is formed, and the open region is etched by means of a known semiconductor processing method, such as, for example, reactive ion etching (RIE). The etching is performed so that the etching depth of the open region becomes equal to or greater than the total thickness of the upper layer 1a′ and the oxide film 3. This enables the surface (top surface) of the lower layer 1 to be exposed. As illustrated in FIG. 3(D), in the open part 15 which is not subjected to masking, a (0001) Si face 1 is exposed, and in a coated part 11 which is subjected to photomasking, the upper layer is left and the C face (intermediate layer) 1a′ is left. Then, the photomask is removed.

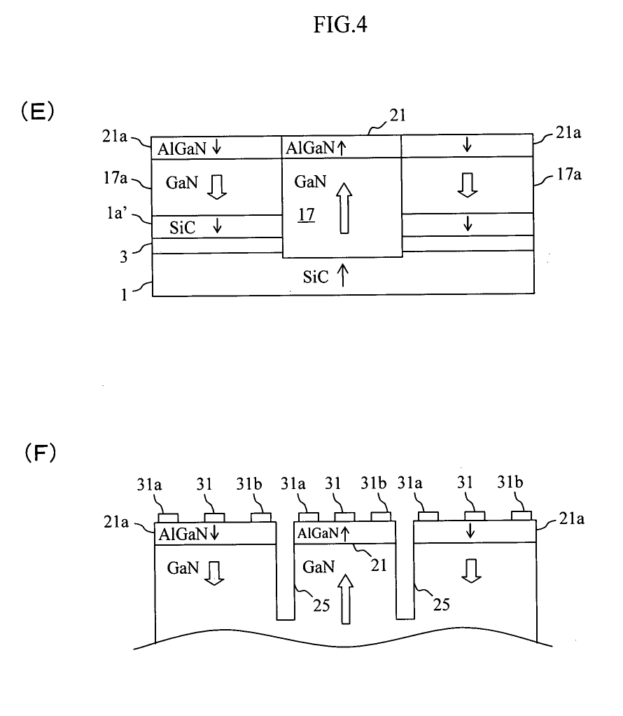

Next, after performing chemical cleaning or gas etching etc. for removing the damage due to reactive ion etching, if necessary, crystal growth of, for example, a group III-nitride (GaN, AlN) is performed. As illustrated in FIG. 4(E), growth of a group III-nitride of, for example, a GaN layer on the SiC 1 having a Si polar face, enables a GaN layer 17 having a Ga polar face where bonds of Ga extend perpendicularly, to be grown. In a region where the SiC layer 1a′ having a reversed polarity on the Si polar face thereof is left, GaN 17a having an N polar face can be grown, where bonds of N extend perpendicularly.

Next, if an AlGaN layer is formed on the substrate surface, an AlGaN layer 21 having a group III-polar face is formed on a GaN layer 17 having a Ga polar face, and an AlGaN layer 21a having an N polar face is formed on a GaN layer 17a having an N polar face. In this manner, patterning of the polarity reversal template enables a group III-nitride crystal having a group III-polar face or a nitrogen polar face to be formed at any position in a plane of the substrate.

After that, by performing general semiconductor forming steps such as an ion implanting step, an electrode forming step (forming source/drain electrodes 31a/31b, and a gate electrode 31), an etching step, and an element isolating step (forming an element isolation region 25), as illustrated in FIG. 4(F), an integrated circuit having a structure where a large number of AlGaN/GaN HEMTs (high electron mobility transistors) having different polar faces are integrated on a single substrate, can be fabricated. In the device structure illustrated in FIG. 4(F), three HEMTs each element-isolated by the element isolation region (for example, trench) 25, and each having a gate electrode 31 and source/drain electrodes 31a/31b are formed (in a practical integrated circuit, much more HEMTs are formed). Here, it is characterized in that the polarity of SiC forming a channel layer where AlGaN/GaN HEMT is formed, differs between the central HEMT and the HEMTs on both sides.

Next, a method for fabricating a semiconductor device according to a second embodiment of the present invention will be described. The present embodiment is an example when the second semiconductor fabricating technology (Smart Cut technology) is used. As illustrated in FIG. 2(D), formation of a laminated structure of a SiC substrate 81a, a SiO₂ layer 84, and a reversed SiC layer 82c, enables a semiconductor structure having the same configuration as that of FIG. 3(B) in the first embodiment of the present invention to be achieved. Subsequently, as illustrated in FIG. 3(C), a SiO₂ side wall is removed, and, subsequently by being subjected to steps in FIGS. 3(D) to 4(E) and 4(F), the same device structure as that of the first embodiment can be produced.

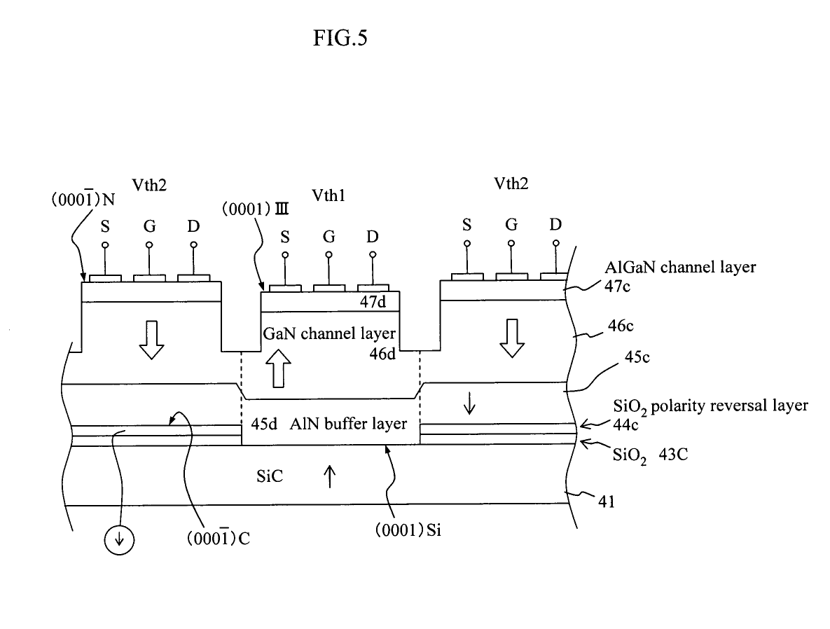

Next, as a first specific example of a more specific device structure, an application example with regard to an integrated circuit of transistors each having a different threshold value, will be described with reference to FIG. 5. In FIG. 5, as the example of an integrated circuit using transistors, a HEMT using a hetero-junction of a group III-nitride, for example, AlₓGa₁₋ₓN/GaN, will be described. Since the HEMT using a hetero-junction of AlₓGa₁₋ₓN/GaN can make full use of the characteristics thereof by being applied to a high frequency device, a power device, and an ultra high-speed device, it is expected to be applied to these devices.

The HEMT having this structure is generally produced by using a multilayer structure where crystals are grown in a c-axis direction. A group III-nitride has strong piezo polarization and spontaneous polarization, and thereby, based on this, according to the direction of the c-axis, a [0001] and a [000-1], with respect to an AlGaN/GaN hetero interface, induction of carriers into the AlGaN/GaN interface is prompted or inhibited. In other words, in the meaning of transistor characteristics, the HEMT is characterized in that the threshold voltage of the transistor is largely shifted depending on the growth direction.

For the HEMT for the purpose of applying to, for example, a high frequency power transistor, causing carriers in the AlGaN/GaN interface to be as many as possible leads to high performance thereof. Therefore, a [0001] direction crystal face is used so that induction of carriers is prompted by the spontaneous polarization and piezo polarization of the [0001] direction crystal face. On the other hand, when an integrated circuit such as an ultra-high speed logic circuit, is produced by using AlGaN/GaN HEMTs, if the HEMTs each having a different threshold value can be produced on a same substrate, the degree of freedom of circuit design will increase to a large extent.

When a conventional method was used (i.e., the polarity reversal template of the present invention was not used), a method for changing a threshold voltage by changing a gate electrode material had to be used. The gate electrode material had to satisfy another demand such as leakage current reduction simultaneously, and thereby it was difficult to change the threshold voltage largely.

The inventor has paid attention to that the threshold voltage can be changed largely by setting the c-axis to a [000-1] direction being the counter direction of the [0001] direction. In other words, if the crystal growth technologies according to the embodiments mentioned-above are used, the polarity of a group III-nitride can be arbitrarily changed to some extent in a plane of the substrate. Accordingly, use of the crystal growth technologies according to the present embodiments allows an integrated circuit of group III-nitride transistors having a plurality of threshold voltages, to be achieved on one substrate.

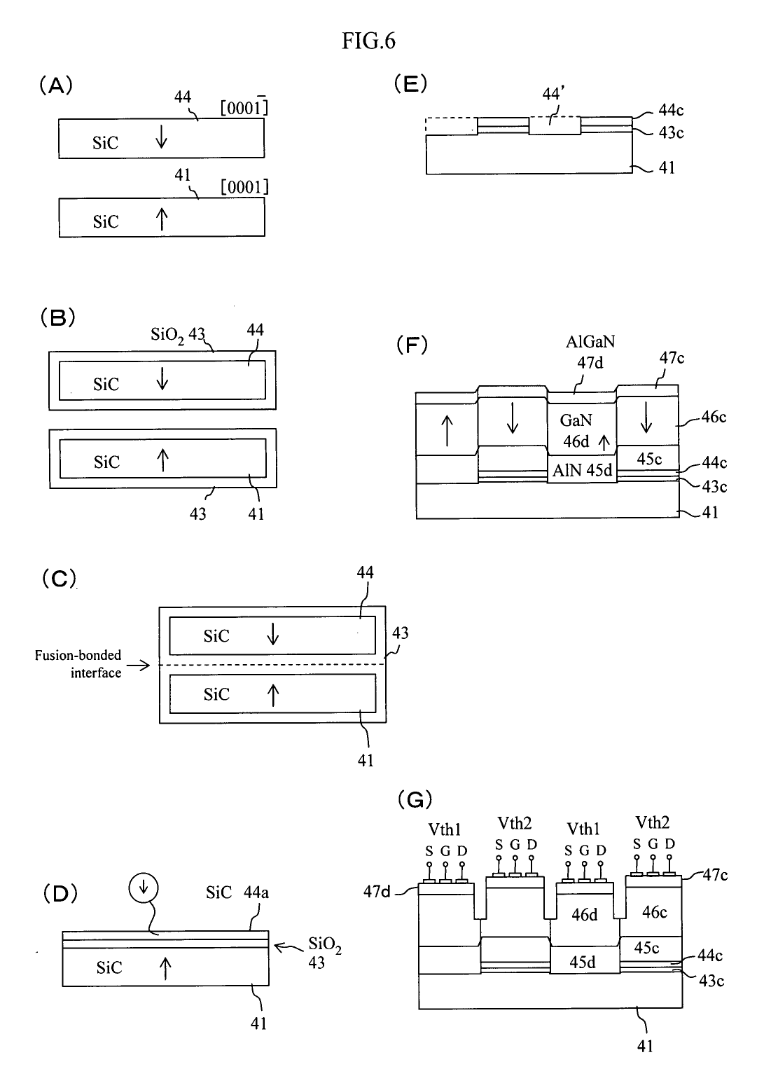

One example of a device structure utilizing the above characteristics will be described with reference to FIG. 5. As being clear from FIG. 5, group III-nitride transistors (Vth1 and Vth2) of central side and right side (or left side), illustrated in FIG. 5, have crystal axes being reverse to each other (each represented by an upward arrow or a downward arrow) in GaN channel layers 46c and 46d being base layers of AlGaN layers 47c and 47d, respectively, and depending on this, each has a greatly different threshold voltage Vth. One example of production methods of these elements, will be described with reference to FIGS. 6(A) to 6(G). The details of FIG. 5 will be described later.

As illustrated in FIG. 6(A), a first SiC substrate 41 having a (0001) face orientation and a second SiC substrate 44 having a (000-1) face orientation, are prepared. An oxide film 43 is formed on a surface of each of the SiC substrates 41 and 44 by subjecting them to oxidation (FIG. 6(B)), and the two SiC substrates 41 and 44 are fusion-bonded to each other by using the technologies of the first and second embodiments (FIG. 6(C)). Subsequently, a part corresponding to the first SiC substrate 41 is thinned by means of polishing etc. (FIG. 6(D) 44a). Next, depending on required regions, by using a known processing technology such as a photo-lithography method and a reactive-ion-etching method, a partial region 44′ of the thinned film 44a on the first SiC substrate 41 is removed, and a partial film (region) 44c of the thinned film 44a is left (FIG. 6(E)). This enables a processed substrate (FIG. 6(E)) to be produced, where a SiC (0001) face 41 and a SiC (000-1) face 44c are formed on the substrate surface, alternately, for example.

After subjecting the processed substrate to surface cleaning and surface control which are suitable for crystal growth of a group III-nitride, by sequentially performing crystal growth of layers containing, for example, an AlN buffer layer 45, a GaN channel layer 46, and an AlGaN barrier layer 47 (FIG. 6(F)), and sequentially performing general device processes such as an etching step for isolation and an electrode forming step, an element structure as illustrated in FIG. 5 is completed (FIG. 6(G) also shows the same structure).

For crystal growth of a group III-nitride, in some cases, better crystal growth can be performed by using a plane having an offset angle of several degrees from the perfect SiC (0001) face or the perfect SiC (000-1) face, rather than using the perfect SiC (0001) face or the perfect SiC (000-1) face. In the above-mentioned description, a case where crystal growth is performed by using the exact (0001) face or the exact (000-1) face has been exemplified; however, in some cases, each face orientation of SiC may be caused to have a shift (offset) from the exact face orientation intentionally so that the grown thin film on the polarity reversal template has better quality. Since there is a difference in growth conditions, it is not necessarily appropriate to suggest the offset angle; however, for example, when a group III-nitride is grown on the template, it is suitable for the offset angle to be equal to or smaller than about 10 degrees. When SiC is grown on the template, it is suitable for the offset angle to be two to nine degrees.

FIG. 5 mentioned above is a view illustrating one example of a HEMT structure having an AlGaN/GaN hetero interface, which is produced according to the above-mentioned steps described with reference to FIG. 6. As illustrated in FIG. 6, the HEMT structure having the AlGaN/GaN hetero interface according to the present embodiment includes HEMTs formed on a region where a laminated structure of a SiO₂ layer 43c and a SiC polarity reversal layer 44c is left on a [0001] SiC substrate 41, and on a region where the laminated structure is removed, respectively. More specifically, devising of combination of AlN buffer layers. 45c/45d on the region where the above-mentioned laminated structure is formed, AlGaN/GaN channel layers 47c/46c (000-1), and AlGaN/GaN channel layers 47d/46d (0001) on the region where the above-mentioned laminated structure is not formed, enables the Vths of the HEMTs to be different from each other like the Vth1 and the Vth2.

In addition, in a general integrated circuit, since transistors each having a different threshold value are necessary, this technology improves the degree of freedom of circuit design, and is also effective for reduction of power consumption. Accordingly, the advantage in that use of the above-mentioned technology enables HEMTs each having a different threshold value to be formed on a same substrate is very large.

In addition, in the above-mentioned example, although the HEMT structure using a group III-nitride has been exemplified, by using the same method, it is also possible to form a device structure by utilizing a group II-oxide having polarity in a similar manner as the group III-nitride. More specifically, if a ZnₓMg₁₋ₓO layer or a ZnO layer is used as the barrier layer, and a ZnO layer or a ZnₓCd₁₋ₓO layer is used as the channel layer, channels can be formed in the interface thereof. Therefore, utilizing of the same crystal growth technology and semiconductor processing technology enables HEMTs each having a different threshold voltage Vth to be formed on a same substrate.

Next, a SiC semiconductor device and a method for fabricating the SiC semiconductor according to a modified example of the first embodiment of the present invention will be described. The crystal growth technology according to the present embodiment is applicable not only to group III-nitrides but also to any materials. More specifically, it is applicable to group II-oxides (substances containing at least any one or more of Zn, Mg and Cd, and oxygen).

When a polarization-reversed substrate is produced, two ways of bonding, that is, bonding of Si polar faces and bonding of C polar faces, can be considered. In both cases, patterning enables a Si polarity and a C polarity to coexist on a surface; however, practically, bonding of Si polar faces is desirable. The reason of this is that since the polishing speed of the Si polar face is slow, a lot of time is required for thinning the upper substrate.

Until this point, although the technology characterized by controlling a polarity has been described, the technology can be expanded, in a viewpoint of flexible control of crystal faces and crystal orientations, as a more generalized technology. For example, as illustrated in FIGS. 7(A) and 7(B), combination of a Si polar face and a non-polar face of (11-20) or (1-100) is also possible. In other words, in a structure illustrated in FIGS. 7(A) and 7(B), two substrates each having a different crystal face are fusion-bonded to each other. Use of such combination of fusion-bonding enables a high performance integrated device to be achieved. In a structure illustrated in FIG. 7(A), a substrate having a (0001) Si polar face 51a, and a substrate having a (11-20) face 51b are prepared, and as illustrated in FIG. 7(B), a rear surface side of the substrate having a (0001) Si polar face 51a, and a surface side of the substrate having a (11-20) face 51b can be fusion-bonded to each other by sandwiching an intermediate layer 53, in the same manner as described-above.

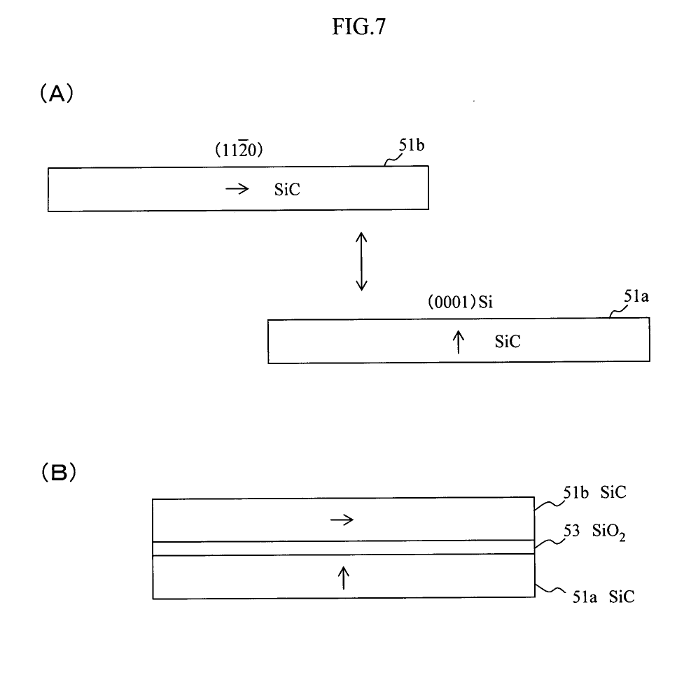

Next, as illustrated in FIG. 8(C), a (11-20) face 51b and the intermediate layer 53 are removed with regard to a certain region (the left side region in the figure). Subsequently, when a GaN layer is grown, a GaN layer 51a′ having a (0001) Si polar face is formed on the SiC substrate 51a, and a GaN layer 51b having a (11-20) face is formed above the SiO₂ intermediate layer 53. The region between the GaN layer 51b having (0001) Si polar face and the GaN layer 51b′ having a (11-20) face is removed, and, as illustrated in FIG. 8(D), an AlGaN layer 55 and an n-type AlGaN layer 51b′ are formed on the GaN layer 51a′ and the high concentration n-type GaN layer 51b′, respectively, and subsequently, a cladding layer 67 of an n-type GaN layer, a GaN/InGaN multiple quantum well layer (MQW) 71, and a cladding layer 73 of a p type GaN layer are formed. A right side region and a left side region are isolated from each other, and in the left side region, source/drain electrodes 57/63, and a gate electrode 61 are formed on the AlGaN layer 55, resulting in completion of an FET (HEMT). In the right region, electrodes 77 and 75 are formed on the high concentration n-type GaN layer 51b′ and the cladding layer 73 of a p type GaN layer, respectively, thus enabling a laser element having a multiple quantum well structure to be formed.

As mentioned above, a high performance GaN-based HEMT can be produced on a Si polar face. On the other hand, since piezo polarization does not occur on a non-polar face, the probability of light emission and recombination of electrons and holes is increased, also enabling a high performance GaN-based laser to be produced. In other words, use of a template substrate having a polar face and a non-polar face enables a high performance electronic device and a high performance optical device to be produced monolithically.

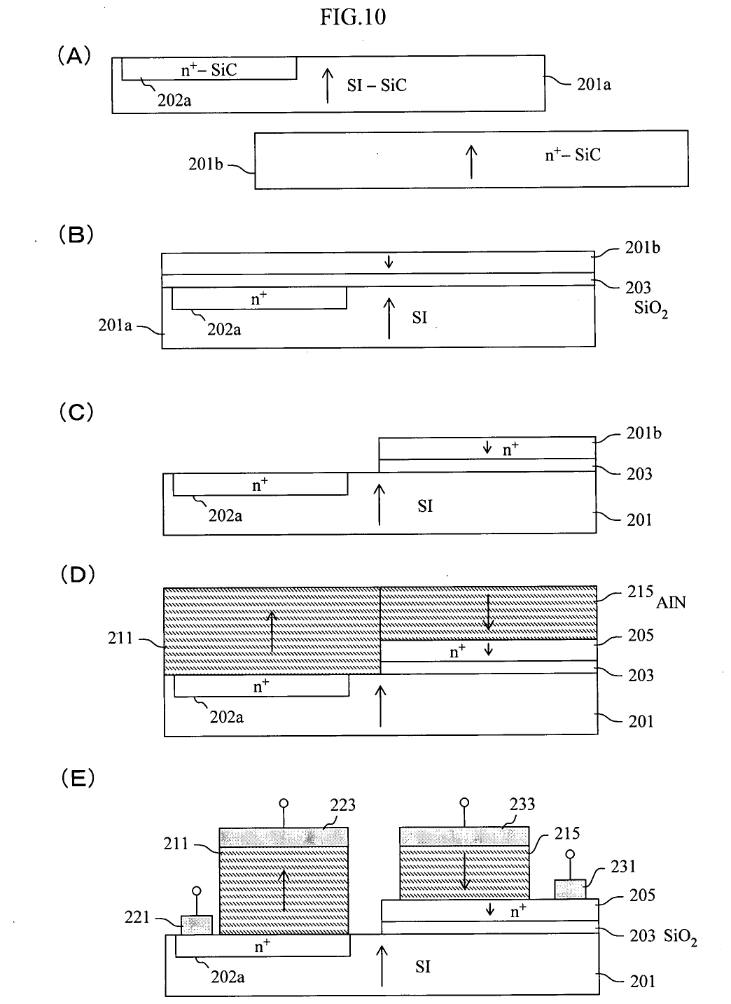

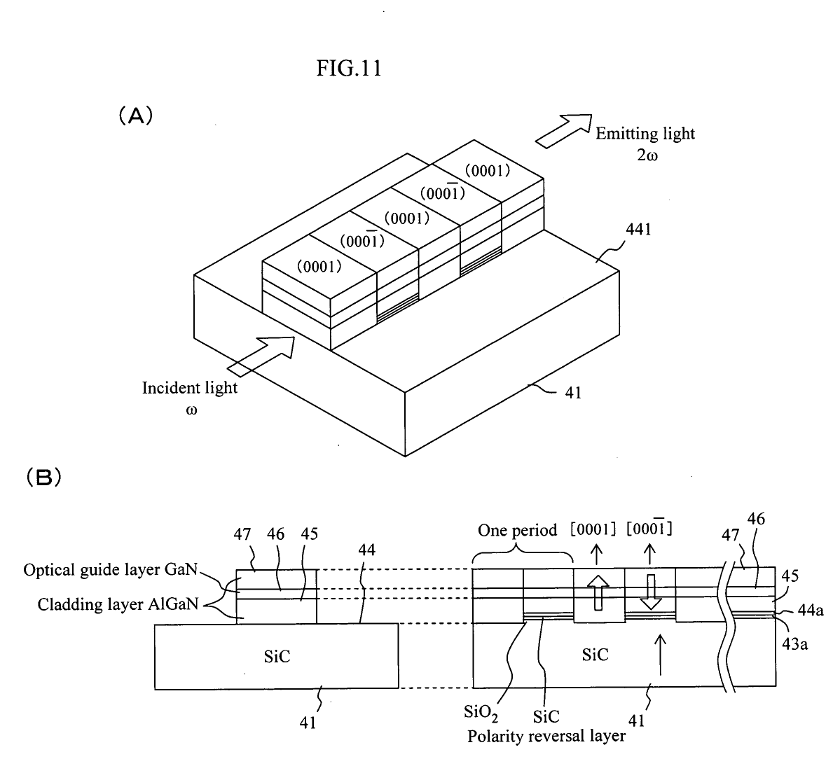

Next, as a second specific example of a more specific device structure of the above-mentioned technology, an example of a non-linear optical element will be described. Use of the semiconductor growth technology and the semiconductor processing technology according to the present embodiment mentioned above enables a high performance non-linear optical element etc. to be achieved. As the example, an example of fabricating a second harmonics generating element will be described with reference to FIGS. 11 and 12. The non-linear optical element according to the second specific example of the present embodiment, as illustrated in FIGS. 11(A) and 11(B), is an non-linear optical element formed on a SiC substrate 41, and is composed of cladding layers 45 and 47 made of AlGaN, and an optical guide layer 46 made of high refractive index GaN, sandwiched by the cladding layers 45 and 47. As mentioned above, use of the technology according to the present embodiment for flexibly controlling a crystal orientation in a plane of the substrate enables a structure where a crystal orientation is modulated periodically with respect to the traveling direction of light to be produced. As illustrated in FIG. 11(A), a light wave of the fundamental wave entering the non-linear optical element as an incident light ω travels along the optical guide layer 46, and the periodical reversal of crystal orientation enables quasi phase matching to be achieved, and highly efficient generation of the second harmonics to be achieved, thus enabling an emitting light 2ω to be obtained.

One example of the method for fabricating the above-mentioned non-linear optical element will be described with reference to FIGS. 12(A) to 12(G). First, as illustrated in FIG. 12(A), a first SiC substrate 41 and a second SiC substrate 44 having a (0001) face orientation and a (000-1) face orientation, respectively, are prepared. An oxide film 43 is formed on a surface of each of the SiC substrates 41 and 44 by subjecting them to an oxidation treatment (FIG. 12(B)), and the two SiC substrates are fusion-bonded to each other (FIG. 12(C)).

Subsequently, a part corresponding to the second SiC substrate 44 is thinned (FIG. 12(D): 44a). Next, in accordance with required periodic reversal, by using a photo-lithography technology and a reactive-ion-etching technology, the thinned film 44a of the second SiC substrate 44 is processed to be removed in stripes. This enables a substrate (FIG. 12(E); regions indicated by reference numeral 441 and reference numerals 44b/43a) to be produced, where a SiC (0001) face and a SiC (000-1) face appears alternately on the substrate surface.

On the substrate produced in this manner, an AlGaN layer 45a to be a first cladding layer, a GaN layer 46a to be an optical guide layer, and an AlGaN layer 45c to be a second cladding layer are grown. Since these group III-nitrides grow by inheriting the SiC face orientation exposed on the surface, a structure where crystal axes are spatially-periodically reversed can be achieved. In other words, a second laminated structure 45a/46a/47a is formed on a first laminated structure 43a/44b, and a third laminated structure 45b/46b/47b is formed on a region where the first laminated structure 43a/44b has not been formed. Finally, a stripe structure for achieving light confinement in a lateral direction that is an in-plane direction of the substrate is formed by using known processing technologies including lithography and reactive ion etching, thus resulting in completion of the non-linear optical element (FIGS. 12(F) and 12(G)).

In the growth of a group III-nitride, in some cases, better crystal growth can be performed not only by using the perfect SiC (0001) face or the perfect SiC (000-1) face, but also by using a plane having an offset angle of several degrees from the perfect SiC (0001) face or the perfect SiC (000-1) face. Accordingly, the face orientations of SiC may have a shift of being equal to or smaller than 10 degrees from each face orientation.

Moreover, when a group III-nitride is grown on a SiC (0001) face and a SiC (000-1) face simultaneously, since the growth process of the group III-nitride may be performed only once, the steps may be eliminated for simplification; however, in some growth methods and conditions, the growth speed of the group III-nitride may largely differs depending on the polar face.

In this case, at the interface where the crystal axis is reversed, discontinuity may occur in the optical guide, the cladding layer, and the surface of crystal growth. Therefore, although the number of steps increases, in order to avoid such a problem, a structure having a little difference in level can be produced by first growing a group III-nitride under the optimal condition with respect to one face orientation; next, after selectively removing the group III-nitride grown in the other face orientation by means of lithography etc., by growing the group III-nitride under the optimal condition with respect to the latter face orientation; and finally, by removing an extra group III-nitride formed on the surface.

As another method, there is also a method where, after the AlGaN layers 45a and 45b to be the first cladding layers are grown as mentioned above, a process for flattening is performed, and subsequently, after the guide layer and the second cladding layer are grown respectively, the flattening process is introduced. Since flattening can be achieved by means of polishing, in general, removal of the damaged layer due to polishing is also necessary, after flattening before growth of the next layer. Since the guide layer is thin, if the difference in growth speed is not large, it is also possible to eliminate the flattening step after the guide layer is grown.

In addition, in the above-mentioned example, instead of group III-nitrides, it is also possible to utilize group II-oxides each having a polarity similarly. Specifically, if ZnₓMg₁. ₓO or ZnO is used as the cladding layer, and ZnO or ZnₓCd₁₋ₓO is used as the optical guide layer, quasi phase matching by means of light confinement and polarity reversal can be achieved. Moreover, even if SiC is used instead of group III-nitrides, the quasi phase matching can also be achieved. However, since it is difficult for SiC to form mixed crystals, it is difficult to achieve a longitudinal optical guide layer using Si₁₋ₓCₓ. Therefore, it is necessary to achieve a light confinement guide by air or other low refractive-index substances by removing a substrate.

Moreover, for modulation of a crystal axis, other than the method where a (0001) and a (000-1) are used as the first and second SiC substrates, respectively, a method using a (11-20) face and a (11-20) face (however, [0001] directions of in-plane crystal orientation of the two are different from each other by about 180 degrees), etc. can also be used. In this case, since, although in-plane crystal orientations thereof are different from each other, planes on which crystals are grown are completely the same ones, there is no difference in growth speed of thin films growing on the planes, and thereby, this method has a very large merit in that a problem of difference in level due to the difference in growth speed can be perfectly solved. This technology where crystal faces are the same ones, and only crystal face orientations are arbitrarily controlled is very effective as the fabricating technology of a non-linear optical element, and applicable to all other devices. The feature in that crystal growths on a template are equivalent, is a feature obtained only from the structure using the technology according to the present embodiment.

However, even in this case, the problem of difference in level existing on the SiC template from the beginning has to be solved. As one method for this is a method where a SiO₂ layer is caused to thin when possible, and the surface SiC substrate is polished as thin as possible. The thickness of the SiO₂ layer can be reduced to several nm by fusion-bonding conditions etc. Moreover, it is also possible to employ a bonding method utilizing SiO₂. Thinning of the surface SiC substrate has a limit due to uneven polishing in a usual polishing technology, and thereby, it is effective to utilize a method such as Smart Cutting.

In addition, in the above-mentioned embodiments, although the technology where crystals each having a different polar face are fusion-bonded by heat through an insulating film such as SiO has been described as examples, it is also possible to bond substrates together utilizing an alloying reaction between metals or between SiC and a metal by using a metal film material etc. with a heating treatment, or instead of the heating treatment. Of course, a bonding technology utilizing a common bonding material may be used. However, there are such restrictions that bonding strength is sufficient, and that metals and the bonding material do not become pollution sources in the subsequent processes, and can withstand heat in the subsequent processes. Moreover, it is also possible to bond SiCs which are brought into contact with each other mechanically without using any bonding layer etc., by maintaining them at a very high temperature. Considering easiness of achievement, bonding strength, heat resistance properties and the like, the bonding through SiO₂ has the largest applicable range.

When the first crystal face and the second crystal face are bonded, if, for a SiC substrate, the total thickness of the silicon oxide film existing in the fusion-bonded boundary between the first SiC substrate and the second SiC substrate is caused to be equal to or smaller than 200 nm, in a process for thermally oxidizing SiC, an oxide film can be easily formed because of the thin thickness. Moreover, the thin thickness of the SiO₂ layer has an effect to cause the difference in level formed on the template to be small.

On the contrary if the total thickness of the silicon oxide film existing in the fusion-bonded boundary between the first SiC substrate and the second SiC substrate is caused to be equal to or greater than 1 micron, in an application for a micro-machine, a free-standing structure can be produced by removing SiO₂ subsequently. Moreover, in an application for an electronic circuit, it is possible to reduce stray capacitances of between the substrate and the device and wiring on its surface, and this is preferable for high frequency and high speed. In other words, according to applications, the thickness of SiO₂ can be adjusted.

Hereinafter, more specific application examples of the technology according to the present embodiment will be described.

### 1) First Application Example:

When the first crystal face and the second crystal face are bonded, any one of structures of 3C, 4H, 6H, and 15R is used as the SiC substrate. At that time, it is preferable that at least one of the first crystal face and the second crystal face lies at an angle being equal to or smaller than 85 degrees from a (0001) Si face (for the 3C; a {111} Si face), and the other of them lies at an angle being equal to or smaller than 85 degrees from a (000-1) C face (for the 3C; a {-1-1-1} C face). At that time, there are two cases of a case where the first crystal face is a Si polar face, and the second crystal face is a C polar face, and a case where the first crystal face is a C polar face, and the second crystal face is a Si polar face. This is a desired structure where two kinds of plane polarities coexist in a broad sense.

### 2) Second Application Example:

The first crystal face and the second crystal face are caused to be same crystal faces or crystal faces being approximately the same with each other; however, their crystal orientations in the in-plane direction are caused to be different from each other. Specifically, it is preferable that the difference in crystal faces be equal to or smaller than 20 degrees and the difference in face orientations be equal to or greater than 10 degrees. For example, both crystal faces may be (0001) Si polar faces; however, a case may be included where bonding is performed in a state where in-plane [1-100] orientation axes are shifted from each other by, for example, 30 degrees. Use of the same face orientation causes crystal growth on the template to be equivalent in both regions, and thereby, a state to be achieved where a thin film growth can be performed under the optimal crystal growth conditions in a region where growth conditions are the same ones, or in any region. Since crystal growth speed and the optimal crystal growth conditions change slowly with respect to the crystal faces, even if both crystal faces are not the same ones, if the difference is equal to or smaller than 20 degrees, they can be substantially considered as same planes. On the contrary, the difference of in-plane orientations is determined according to the desired function. For example, in the above-mentioned non-linear optical element, theoretically, it is desirable for each in-plane orientation to be rotated by exactly 180 degrees with respect to the other in-plane orientation.

### 3) Third Application Example:

When the first crystal face and the second crystal face are bonded, any one of structures of 3C, 4H, 6H, and 15R is used as the SiC substrate, it is configured so that at least one of the first crystal face orientation and the second crystal face orientation lies at an angle being equal to or smaller than 30 degrees from a (0001) Si face (for the 3C; a {(111} Si face) or a (000-1) C face (for the 3C; a {-1-1-1} C face), and the other crystal face orientation lies at an angle being equal to or smaller than 15 degrees from a {11-20} face or a {1-100} face (for the 3C; a {100} or a {110}). This corresponds to combination of a face having a polarity (polar face), and a face having no polarity (non-polar face). In the above-mentioned examples, the application examples for integrating transistor and light emitting devices of a group III-nitride are mentioned; however, for example, when for a sensor etc., kind of reactive gas or the like differs depending on crystal faces, the SiC substrate can be utilized for an application where a plurality of sensors are integrated on a same substrate, or the like.

### 4) Fourth Application Example:

When the first crystal face and the second crystal face are bonded, any one of structures of 3C, 4H, 6H, and 15R is used as the SiC substrate, it is configured so that the face orientation of the first crystal face and the face orientation of the second crystal face are the same face orientations, which lie at an angle being equal to or smaller than 15 degrees from a {11-20} face or a {1-100} face (for the 3C; a {100} or a {110}), and in-plane crystal orientations of the first crystal face and the second crystal face are different from each other by an angle being equal to or greater than 170 degrees. The SiC substrate has a structure where the first crystal face and the second crystal face are the same non-polar faces, and have different in-plane orientations. This is a more specific example of the second application example 2), and specifically useful for production of a non-linear optical element, a highly functional micro-machine, a piezo-electric element or the like.

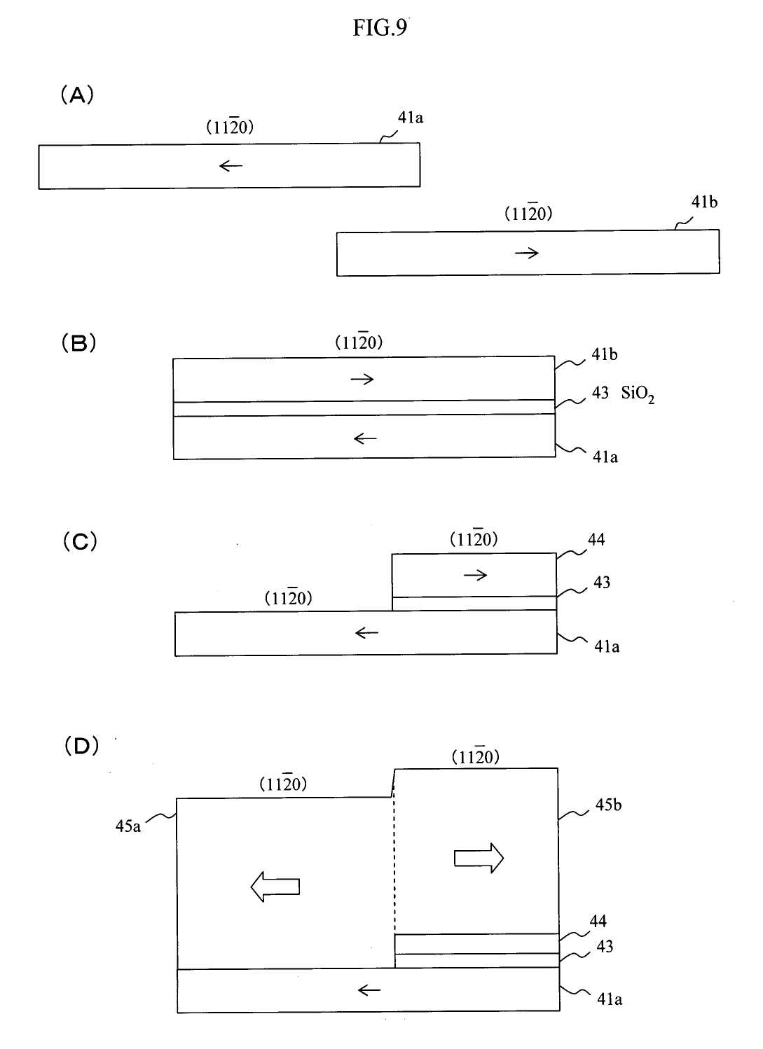

Next, a method for fabricating a semiconductor device according to a third embodiment of the present invention will be described with reference to drawings. FIGS. 10(A) to 10(E) are views illustrating the method for fabricating a semiconductor device according to the present embodiment. As illustrated in FIG. 10(A), a first SiC substrate 201a and a second SiC substrate 201b each having (0001) Si polar face are prepared. In the first substrate 201a, an n⁺ region 202a is formed in an SI (Semi-insulating) substrate. The second substrate 201b is an n⁺ conductivity SiC substrate. As illustrated in FIG. 10(B), the first SiC substrate 201a and the second SiC substrate 201b are laminated to each other by forming a relatively thick intermediate layer SiO₂ 203 in a state where the surface of the second substrate 201b is brought into contact with the surface of the first substrate 201a.

As illustrated in FIG. 10(C), by removing the intermediate layer 203 and the SiC layer 205 on a partial region of the first substrate 201a, the n⁺ region 202a is exposed on the partial region. Subsequently, a first and second AlN layers 211 and 215 are formed on a first region which includes the region where the n⁺ region 202a is formed, and which is subjected to the above-mentioned selective removal step, and a second region where an n⁺-SiC layer 205 having a (000-1) C polar face is formed, respectively (FIG. 10(D)). The AlN layer formed on the first region inherits the polarity of the first region and the AlN layer formed on the second region inherits the polarity of the second region. A first electrode 221 is formed on the region of the first region where the p⁺ layer 202a is exposed, and a second electrode 223a is formed on the first AlN layer 211. On the other hand, in the second region, a third electrode 231 is formed on the SiC layer 205, and a fourth electrode 233b is formed on the second AlN layer 215. This enables a piezo-electric element to be formed in each region, where the electrodes of each element are independent to the electrodes of the other element, and the polarity of each element is reversed to the polarity of the other element (FIG. 10(E)). In addition, the SiO₂ layer 203 that is an intermediate layer also acts as an insulation layer with respect to the substrate 201. In this manner, formation of structures on both faces to be fusion-bonded before fusion-bonding them causes drawing electrodes from individual elements, and embedding devices such as a transistor and a diode into the fusion-bonded interface to be possible, thus enabling a more highly functional element to be achieved.

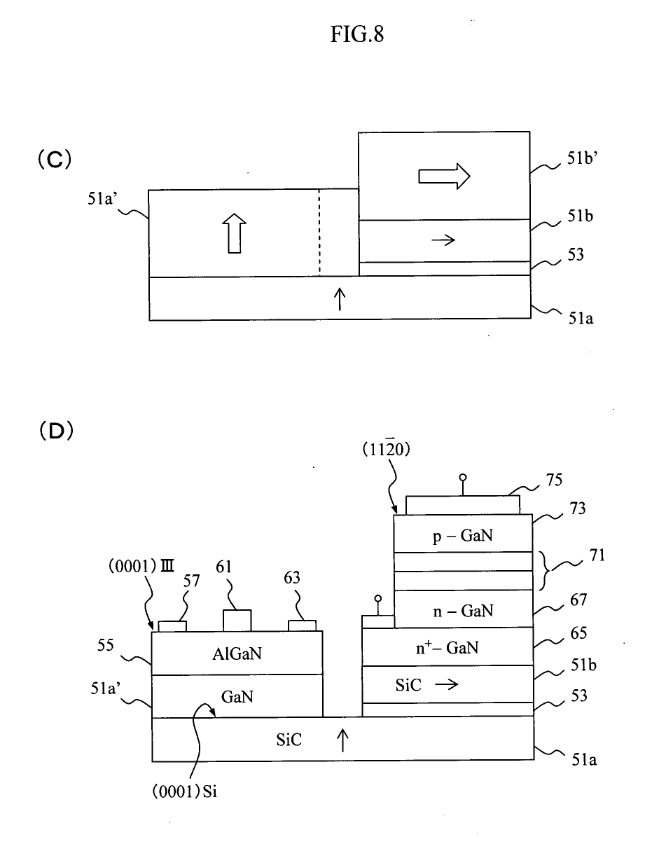

Next, a method for fabricating a semiconductor device according to a fourth embodiment of the present invention will be described with reference to drawings. FIGS. 9(A) to 9(D) are views illustrating the method for fabricating a semiconductor device according to the present embodiment. As illustrated in FIG. 9(A), first, a first SiC substrate 41a and a second SiC substrate 41b each having a (11-20) non-polar face are prepared. As illustrated in FIG. 9(B), the first SiC substrate 41a and the second SiC substrate 41b are fusion-bonded to each other by forming an intermediate layer SiO₂ 43 so that in-plane crystal orientations, specifically, [0001] axis directions are different from each other by 180 degrees. If necessary, the second SiC substrate 41b is made thin.

As illustrated in FIG. 9(C), by selectively removing the intermediate layer 43 and the thinned second SiC substrate 44 on a partial region of the first substrate 41a, a first substrate surface, that is, a (11-20) non-polar face with its [0001] axis facing to the right, is exposed in the region. On the other hand, a remaining region where the intermediate layer 43 and the thinned second SiC substrate 44 has not been removed has a (11-20) non-polar face similarly, but with its [0001] axis facing to the left.

As illustrated in FIG. 9(D), by growing SiC, a group III-nitride, a group II-oxide, or the like on both regions, thin films each inheriting the direction of [0001] axis are grown. In this case, since each surface is the same (11-20) face no matter what its direction is, optimal crystal growth can be performed for both regions under same crystal growth conditions. Moreover, there is a feature in that crystal growth speeds in both regions are equal to each other.

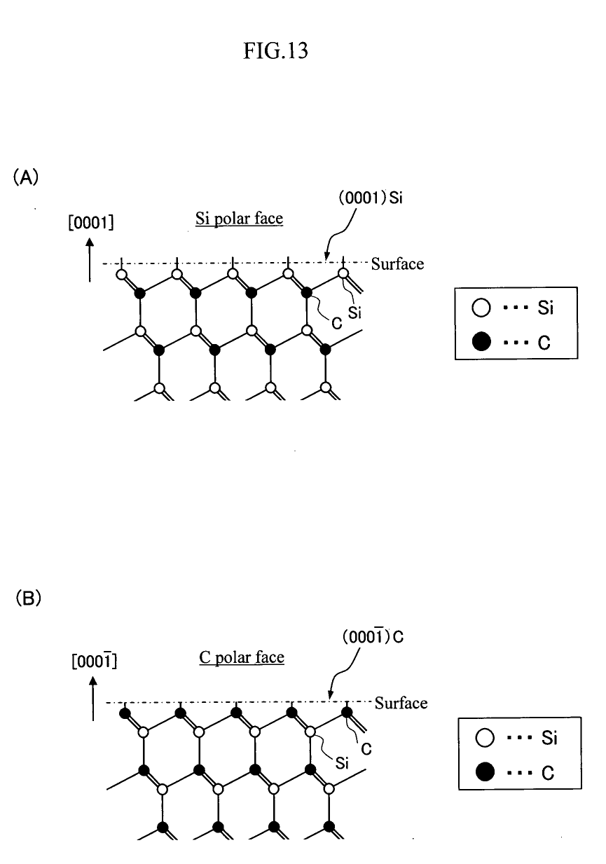

In a waveguide or a device utilizing electric conductivity in the in-plane direction, continuity between thin films each produced on a different crystal face becomes important. In order to maintain the continuity, as described with reference to FIGS. 12(A) to 12(G), flattening step of surface by means of polishing etc., may be performed if necessary. As one example utilizing such a technology, for example, an example where flattening is performed after the first thin film growth step will be described with reference to FIGS. 14(A) to 14(H). FIGS. 14(A) to 14(H) are views illustrating examples of steps derived from the steps in FIGS. 12(A) to 12(G). After performing the steps in FIGS. 14(A) to 14(E), corresponding to the steps in FIGS. 12(A) to 12(E), respectively, are performed, a thin film having a film thickness equal to or greater than that of the difference in level existing on the surface in FIG. 14(E) is deposited on the structure illustrated in FIG. 14(E). By using a thin film material such as SiC, AlN, GaN, or ZnO as the thin film material, epitaxial growth is performed. In the figures, an example using SiC will be described. However, for some kinds of devices, epitaxial growth of another material, or deposition of poly-crystals each having orientation may be utilized.

Flattening the surface of the thin film material by etching the thin film material by means of polishing, CMP, or ion-beam sputtering etc. after the step illustrated in FIG. 14(E) enables such a structure illustrated in FIG. 14(G) to be obtained. The structure illustrated in FIG. 14(E) has both a region where a laminated structure of a SiO₂ layer 43c and a SiC polarity reversal layer 44c is left on the surface of SiC 41, and a region where the laminated structure was removed, and has SiC 81c formed on each region and flattened, thus resulting in formation of a surface where, for example, a SiC (0001) face 81d and a SiC (000-1) face 81c become even with each other (FIG. 14(G)). At the time of FIG. 14(G), since the heights of the surfaces of a SiC (0001) face 81d and a SiC (000-1) face 81c are substantially even, if, in the subsequent step, thin films (of AlGaN 45, GaN 46 and AlGaN 47) are deposited on these surfaces by using a thin film deposition method having such a condition that crystal growth speeds on the crystal faces are substantially equal to each other, a device including a waveguide having a little difference in level can be produced by using a laminated structure of AlGaN 45a, GaN 46a, and AlGaN 47a, and a laminated structure of AlGaN 45b, GaN 46b, and AlGaN 47b neighboring to the former structure in a wave-guide direction.

In addition, in FIGS. 14(A) to 14(H), the example using a (0001) face and a (000-1) face as the first and second crystal faces, respectively, has been described. However, if an element is fabricated in the same steps as mentioned-above where a plane such as a (11-20) face that is perpendicular to a (0001) face is used as both crystal faces, and only in-plane crystal orientations are changed, steps can be simplified in the viewpoint that, since theoretically, both crystal faces are the same in the thin film deposition process, difference in crystal growth speed of a thin film does not occur, and thereby, flattening can be achieved naturally (flattening steps can be eliminated or simplified), thus resulting in a very effective method.

Moreover, even in the case illustrated in FIGS. 14(A) to 14(H), where the flattening step is required, for the difference in level of the surface at the time of FIG. 14(E), the less, the better. Because, when a thin film is grown in the structure in FIG. 14(E), until thin films grown on the region of both (0001) face and (000-1) face, respectively, are brought into contact with each other, crystal growth advances not only in the longitudinal direction but also in the lateral direction. Because, in practice, this does not always cause the width of the stripe to be kept even on the surface as illustrated in FIG. 14(H), rather, causes the width to be widen a little at a convex portion. In addition, it is also possible to design the width of the stripe produced in FIG. 14(E) in anticipation of the change of the stripe width due to crystal growth; however, since the spread due to the growth process is a parameter depending on various kinds of growth conditions, it is desirable to cause the difference in level to be small so that the thin films of both regions are brought into contact with each other immediately after the beginning of the thin film deposition step. More, specifically, it is preferable to suppress the difference in level to be substantially equal to or smaller than 1/10 of the stripe width.

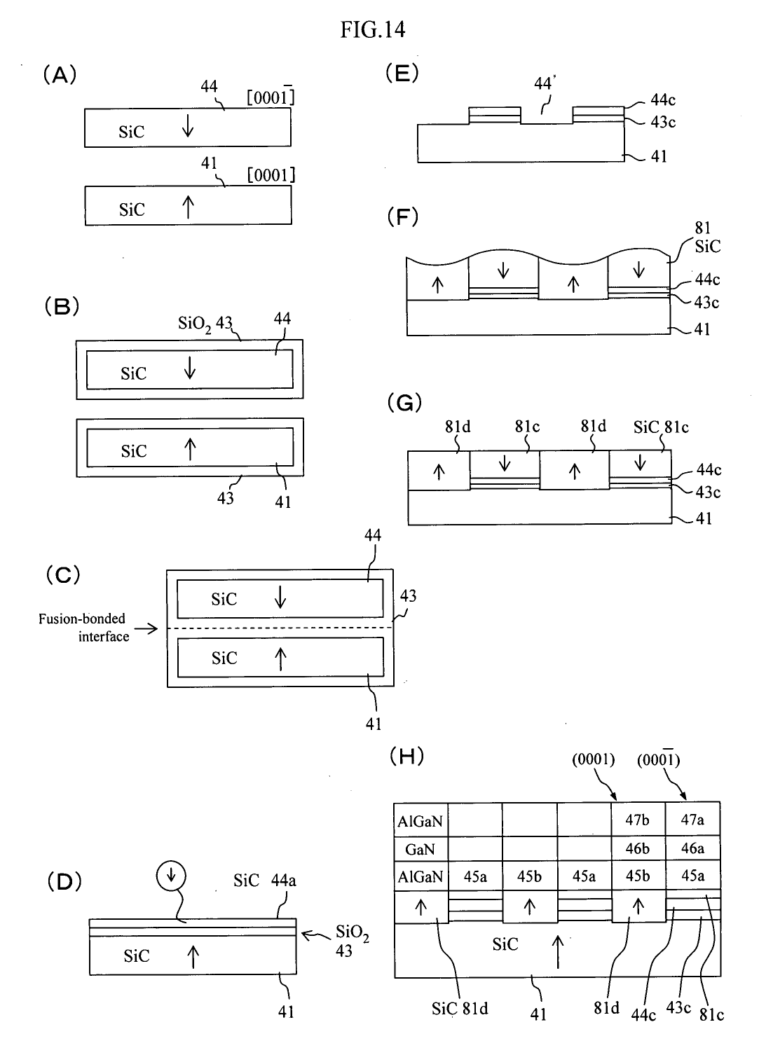

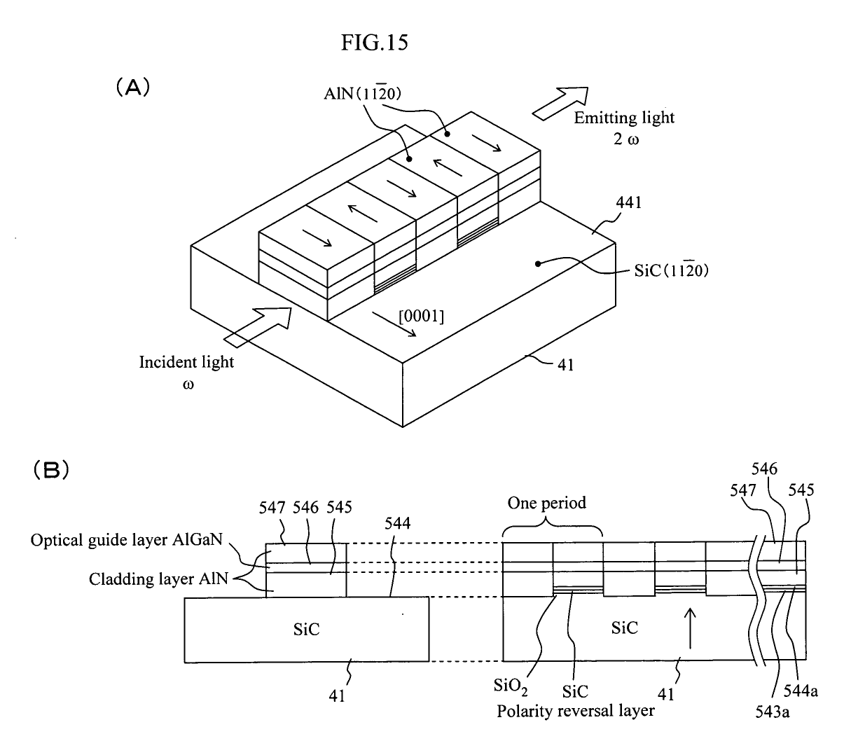

Next, another example will be described with reference FIGS. 15(A) and 15(B). The element illustrated in FIGS. 15(A) and 15(B) is a non-linear optical element using AlGaN 546 as a guide layer, and AlNs 545 and 547 as cladding layers and having a periodic polarization reversal structure. Use of AlGaN 546 having a high content of Al composition as the guide layer, and use of AlNs 545 and 547 as the cladding layers enable absorption due to transition between bands to be suppressed, and thereby, enable the non-linear optical element to be used to a shorter wavelength region.

In addition, if required, it is also possible to use AlGaN as the cladding layer, and also possible to use a film containing small amount of In or B as the cladding layer and the guide layer. Although the length of one region with regard to the traveling direction of light is determined depending on the desired non-linear function, it is about 0.1 μm to 200 μm. It is possible for the number of periods to be set to several periods to several tens of periods, or in some cases, to several thousands of periods.

In addition, in FIGS. 11(A) and 11(B), periodic polarization reversal is performed toward the device surface; however, in FIGS. 15(A) and 15(B) polarization reversal is performed in a plane. Although, in both cases of FIGS. 11(A) and 11(B) or of FIGS. 15(A) and 15(B), effect of quasi phase matching due to periodic polarization reversal can be obtained, in the case of FIGS. 15(A) and 15(B), as described below, there is a very excellent feature in a viewpoint of production of an element, and thereby, as a result, it is possible to produce more easily an element having a few loss.

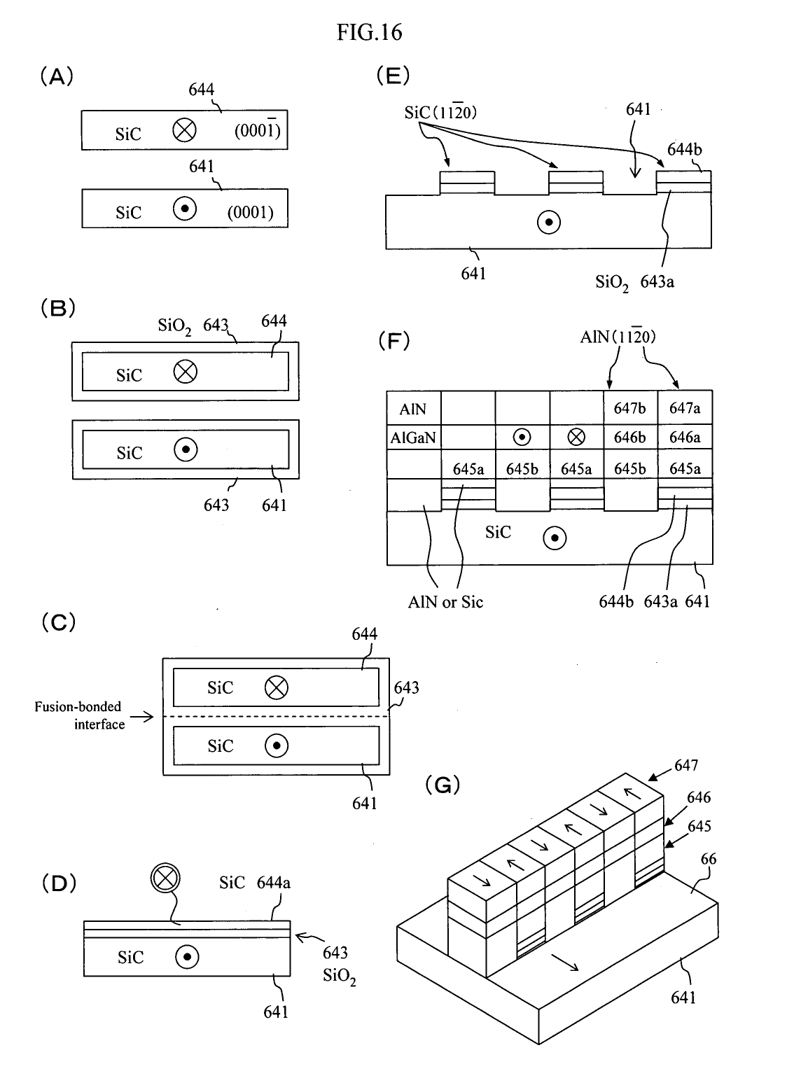

The method for fabricating the element structure illustrated in FIGS. 15(A) and (B) will be described with reference to FIGS. 16(A) to 16(G). As mentioned-above, in order to achieve the continuity of waveguide in high accuracy, it is desirable to use a plane perpendicular to a (0001) face as the crystal orientation. Although, there are a (1-100), and a (11-20) etc., as candidates for such a plane, here an example using a (11-20) will be described. Using the same method as the method that has been described (refer to FIGS. 12(A) to 12(G)), by performing steps such as formation of an oxide film, fusion-bonding, thinning by means of polishing, and patterning, the structure as shown in FIG. 16(E) is produced. In addition, in FIGS. 16(A) to 16(G), an x mark in a white circle indicates an arrow toward depth direction and a dot mark in a white circle indicates an arrow toward near side direction. In production of the structure in FIG. 16(E), as has been described, a method for directly fusion-bonding SiCs without using oxidation, and Smart Cut technology etc. instead of thinning by means of polishing may be used. In FIG. 1.6 (E), a repeated structure of both a laminated structure of SiO₂ 643a/SiC 644a and a structure where the SiC (11-20) face is exposed, toward the direction along the substrate surface, is formed on SiC 641 indicated by the arrow toward near side direction.

Epitaxial growth of SiC or AIN is performed with respect to the structure in FIG. 16(E) corresponding to that in FIG. 12(E) at a thickness being equal to or greater than the difference in level illustrated in FIG. 16(E), and subsequently, the surface of the structure is flattened by means of a method such as mechanical polishing or chemical-mechanical polishing. After that, by means of epitaxial growth of a nitride, AlN cladding layers 645a and 645b, AlGaN guide layers (active layers) 646a and 646b, and AlN cladding layers 647a and 647b are grown. Since crystal orientations of two kinds of regions exposed to the surface are equivalent to each other, there is no difference in crystal growth speed, continuity between neighboring regions is ensured in accuracy at which polishing is performed first. This enables an optical waveguide with extremely high accuracy to be achieved, thus enabling a high performance non-linear optical element to be fabricated and achieved, where light scattering loss due to discontinuity of the waveguide is reduced to the utmost limit (refer to FIGS. 15(A) and (B)).

In other words, as illustrated in FIGS. 16(E) and FIG. 16(G), a second laminated structure 645a/646a/647a is formed on a first laminated structure 643a/644b, and a third laminated structure 645b/646b/647b is formed on a region on which the first laminated structure 643a/644b has not been formed. Finally, a stripe structure for achieving light confinement of the lateral direction that is an in-plane direction of the substrate is formed by using a known processing technology including lithography and reactive ion etching, and resulting in completion of a non-linear optical element.

### INDUSTRIAL APPLICABILITY

The present invention is applicable not only to a device which is produced by growing a group III-nitride or a group II-oxide, but also to a semiconductor device composed only SiC so as to achieve an integrated device etc. having a new function. Moreover, according to the present invention, a SiC-based polarity reversal layer can be produced easily and in high accuracy. In particular, it is applicable to various fields, such as a waveguide type non-linear optical device, HEMT of an E/D configuration, a micromachine, and isolation between elements.

1. A method for fabricating a semiconductor device, comprising:
a step for preparing a first SiC substrate having a first crystal face and a second SiC substrate having a second crystal face;
a step for bonding the first SiC substrate and the second SiC substrate so that the rear surface of the first crystal face and the second crystal face are brought into contact with each other; and
a step for completely removing the first SiC substrate at a partial region in the plane thereof and for exposing the second crystal face being the surface of the second SiC substrate upon the surface of the substrate after bonded, on the surface of the substrate, a structure where the first crystal face of the first SiC substrate and the second crystal face of the second SiC substrate exist mixedly, being formed so that two kinds of crystal face of the first crystal face and second crystal face appearing on the surface of the substrate are different from each other in at least one of crystal face orientation and in-plane crystal orientation.

2. A method for fabricating a semiconductor device, comprising:
a step for preparing a first SiC substrate having a first crystal face and a second SiC substrate having a second crystal face;
a step for ion-implanting hydrogen or rare gas into the rear surface of the first crystal face of the first SiC substrate so that the concentration thereof becomes maximum at a certain depth from the rear surface;
a step for fusion bonding the first SiC substrate and the second SiC substrate by arranging the substrates so that the rear surface of the first crystal face and the second crystal face are brought into contact with each other and by subjecting the substrates to a thermal treatment, and for causing the substrates to peel automatically at the vicinity where the concentration of the implanted atoms is maximum; and
a step for completely removing the first SiC substrate in a partial region on the surface of the second SiC substrate, which is kept bonded to the second SiC substrate and left on the surface of the second SiC as a thin film after peeling, and for exposing the second crystal face being the surface of the second SiC substrate upon the surface of the substrate after bonded, on the surface of the substrate, a structure where the first crystal face of the first SiC substrate and the second crystal face of the second SiC substrate exist mixedly, being formed so that two kinds of crystal face of the first crystal face and second crystal face appearing on the surface of the substrate are different from each other in at least one of crystal face orientation and in-plane crystal orientation.

3. The method for fabricating a semiconductor device according to claim 1 or 2, comprising:
a step for performing a step of forming a silicon dioxide film on both planes or one plane where the first SiC substrate and the second SiC substrate are brought into contact with each other, and for subsequently arranging the first SiC substrate and the second SiC substrate so that the rear surface of the first crystal face and the second crystal face are brought into contact with each other, and for fusion-bonding the substrates by means of a heat treatment.

4. The method for fabricating a semiconductor device according to claim I or 2, comprising:
a step for performing a step of forming a metal film on both planes or one plane where the first SiC substrate and the second SiC substrate are brought into contact with each other, and for subsequently arranging the first SiC substrate and the second SiC substrate so that the rear surface of the first crystal face and the second crystal face are brought into contact with each other, and for fusion-bonding the substrates by means of a heat treatment.

5. The method for fabricating a semiconductor device according to claim 1 or 2, wherein crystal face orientations of the first crystal face and the second crystal face are different from each other by an angle being equal to or greater than 5 degrees.

6. The method for fabricating a semiconductor device according to claim 1 or 2, wherein
as the SiC substrates, any one of structures of 3C, 4H, 6H, and 15R is used, one of the first crystal face and the second crystal face lies at an angle being equal to or smaller than 85 degrees from (0001) Si face (for 3C; {111} Si face), and the other of them lies at an angle being equal to or smaller than 85 degrees from (000-1) C face (for 3C; {-1-1-1} C face).

7. The method for fabricating a semiconductor device according to claim 1 or 2, wherein
face orientations of the first crystal face and the second crystal face are a same face orientation or difference between them is equal to or smaller than 20 degrees, and difference in in-plane direction crystal orientations is equal to or smaller than 10 degrees.

8. The method for fabricating a semiconductor device according to claim 1 or 2, wherein
as the SiC substrates, any one of crystal structures of 3C, 4H, 6H, and 15R is used, a crystal face orientation of one of the first crystal face and the second crystal face lies at an angle being equal to or smaller than 30 degrees from (0001) Si face (for 3C; {111} Si face) or (000-1) C face (for 3C; {-1-1-1} C face), and the other crystal face lies at an angle being equal to or smaller than 15 degrees from {11-20} face or {1-100} face (for 3C; {100}, {110} or {1-10}).

9. The method for fabricating a semiconductor device according to claim 1 or 2, wherein
as the SiC substrates, any one of crystal structures of 3C, 4H, 6H, and 15R is used, face orientations of the first crystal face and the second crystal face are a same face orientation, which lies at an angle being equal to or smaller than 15 degrees from {11-20} face or {1-100} face (for 3C; {100}, {110} or {1-10}), and in-plane crystal orientations of the first crystal face and the second crystal face are different from each other by an angle being equal to or greater than 5 degrees.

10. The method for fabricating a semiconductor device according to claim 1 or 2, wherein
as the SiC substrates, any one of crystal structures of 3C, 4H, 6H, and 15R is used, face orientations of the first crystal face and the second crystal face are a same face orientation, which lies at an angle being equal to or smaller than 30 degrees from (0001) Si face (for 3C; {111} Si face) or (000-1) C face (for 3C; {-1-1-1} C face), and in-plane crystal orientations of the first crystal face and the second crystal face are different from each other by an angle being equal to or greater than 30 degrees.

11. The method for fabricating a semiconductor device according to claim 1 or 2, wherein
total thickness of silicon dioxide films existing in bonded or fusion-bonded boundary between the first SiC substrate and the second SiC substrate is equal to or smaller than 200 nm.

12. The method for fabricating a semiconductor device according to claim 1 or 2, wherein
total thickness of silicon dioxide films existing in bonded or fusion-bonded boundary between the first SiC substrate and the second SiC substrate is equal to or greater than 1 micron.

13. The method for fabricating a semiconductor device according to claim 1 or 2, comprising:
a step for thinning or flattening the first SiC substrate on the entire surface of the substrate, after bonding or fusion-bonding is performed.

14. The method for fabricating a semiconductor device according to claim 1 or 2, wherein
as the first SiC substrate, a substrate which is thinned to be equal to or smaller than 50 microns, is utilized.

15. The method for fabricating a semiconductor device according to claim 1 or 2, comprising:
a step for forming a specific structure on at least one of both the rear surface of a first crystal face of the first SiC substrate and a second crystal face of the second SiC substrate in advance.

16. The method for fabricating a semiconductor device according to claim 1 or 2, comprising:
a step for growing an arbitrary thin film on a SiC substrate on which a surface structure has been formed, where the first crystal face and the second crystal face exist mixedly on the surface, and forming thin films on the first crystal face and the second crystal face of the SiC substrate, each having a different feature.

17. The method for fabricating a semiconductor device according to claim 16, wherein the thin film is a single crystal or polycrystals having orientation, of SiC, a group III-nitride, or a group II-oxide.

18. A monolithic device, wherein
as a first SiC substrate and a second SiC substrate, any one of SiC substrates having a crystal structure of 3C, 4H, 6H, and 15R is used; as a first crystal face, (0001) Si face or (000-1) C face (in a case of 3C structure, {111} Si face or {-1-1-1} C face), or a crystal face at an angle being equal to or less than 30 degrees from these faces, is used; and as a second crystal face, {1-100} face, or {11-20} face (in a case of 3C structure, {100} Si face or {110} Si face, or {1-10} Si face) or a crystal face at an angle being equal to or smaller than 15 degrees from the faces, is used; and, a transistor or diode using SiC or a group III-V or II-VI-semiconductor is formed on the first crystal face, and a light emitting diode, laser diode, or photodiode using a group III-V or II-VI-semiconductor is formed on the second crystal face.

19. A method for fabricating a piezoelectric device, a sensor device, or a micro-machine comprising:
a step for preparing a first SiC substrate and a second SiC substrate in both of which a high concentration impurity region having a second conductivity-type being different from a first conductivity-type is locally formed in a semi-insulating or first conductivity-type substrate having SiC (0001) Si face or SiC (000-1) C face, or a crystal face at an angle being equal to or smaller than 10 degrees from the faces;
a step for bonding the first substrate and the second substrate so that the surfaces thereof are brought into contact with each other;
a step for exposing the surface of the high concentration impurity region by selectively removing the intermediate layer and the SiC layer of the first substrate; and
a step for forming a film of a group III-nitride or a group II-oxide, and for removing the deposited films of respective partial regions of the first substrate and the second substrate, and for forming electrodes on the removed region and the group III-nitride film or group II-oxide film, respectively.

20. A non-linear optical element comprising:
a SiC substrate on which a first crystal face and a second crystal face are formed; and
a stripe structure where a first laminated structure formed on the SiC substrate, which has a first lower clad formed on the first crystal face and inheriting the properties of the first crystal face, a first active layer, and a first upper cladding layer, and a second laminated structure which has a second lower clad formed on the second crystal face and inheriting the properties of the second crystal face, a second active layer, and a second upper cladding layer, are arranged alternately in-plane direction of the substrate,
wherein
the first crystal face and the second crystal face are different from each other in at least one of the crystal face orientation and in-plane crystal orientation.

21. A semiconductor device comprising:
a SiC substrate on which a first crystal face and a second crystal face are formed; and
a structure formed on the substrate; of both a first field effect transistor using, as a channel layer, a first layer which is formed on the first crystal face and inherits the properties of the first crystal face, and a second field effect transistor using, as a channel layer, a second layer which is formed on the second crystal face and inherits the properties of the second crystal face,
wherein,
the first crystal face and the second crystal face are different from each other in at least one of crystal face orientation and in-plane crystal orientation.

22. The method for fabricating a semiconductor device according to claim 1 or 2, comprising:
a step for growing a thin film on a SiC substrate on which a surface structure is formed, where the first crystal face and the second crystal face exist mixedly, and for subsequently flattening the surface.

23. The method for fabricating a semiconductor device according to claim 22, wherein the thin film is flattened after being grown to an arbitrary thickness being equal to or greater than difference in level existing on the surface of the SiC substrate.

24. The method for fabricating a semiconductor device according to claim 22, wherein the thin film is a single crystal or polycrystals having orientation, of SiC, a group III-nitride, or a group II-oxide.

25. The method for fabricating a semiconductor device according to claim 21, wherein at least one of the first or the second cladding layer and the active layer is a nitride containing Al.

26. The method for fabricating a semiconductor device according to claim 21, wherein both of the first crystal face and the second crystal face are planes being perpendicular to (0001) face.

27. The method for fabricating a semiconductor device according to claim 21, comprising: at least one or more steps for performing flattening after an arbitrary thin film constituting the stripe structure is grown.

28. A semiconductor device comprising:
a flat structure of both a SiC substrate having a first crystal face, and a SiC layer having a second crystal face, which layer is formed through a fusion-bonded layer formed on the SiC substrate, or directly formed on the SiC substrate with no fusion-bonded layer,
wherein
the first crystal face and the second crystal face are different from each other in at least one of crystal face orientation and in-plane crystal orientation.

29. A semiconductor device comprising:
a second structure including a laminated structure of both a SiC substrate having a first crystal face and a SiC layer having a second crystal face, which layer is formed through a fusion-bonded layer or directly formed with no fusion-bonded layer, on an certain region of the SiC substrate,
wherein
the first crystal face and the second crystal face are different from each other in at least one of crystal face orientation and in-plane crystal orientation.

30. A semiconductor device comprising:
a SiC substrate having a first crystal face;
a first structure having the first crystal face directly formed on the surface of the SiC substrate; and
a second structure being formed on a different region of the surface of the SiC substrate from a region where the first structure is formed, and including a laminated structure of both a SiC layer having a second crystal face and a layer having the second crystal face,
wherein
the first crystal face and the second crystal face are different from each other in at least one of crystal face orientation and in-plane crystal orientation.

31. The semiconductor device according to claim 30, comprising:
a fusion-bonded layer disposed between a SiC polarity reversal layer and the layer having the second crystal face.

32. The semiconductor device according to claim 30, wherein the upper face is flattened, where the first structure and the second structure are formed.

33. A The method for fabricating a semiconductor device according to claim 1, further comprising:
a step for growing an arbitrary thin film on a SiC substrate on which a surface structure has been formed, where the first crystal face and the second crystal face exist mixedly, and for then forming thin films on the first crystal face of the first SiC substrate and the second crystal face of the second SiC substrate, each inheriting a different feature of the first crystal face or the second crystal face by means of epitaxial growth or growth of polycrystals having orientation.

34. The method for fabricating a semiconductor device according to claim 2, further comprising:
a step for growing an arbitrary thin film on a SiC substrate on which a surface structure has been formed, where the first crystal face and the second crystal face exist mixedly on the surface, and for then forming thin films on the first crystal face of the first SiC substrate and the second crystal face of the second SiC substrate, each inheriting a different feature of the first crystal face or the second crystal face by means of epitaxial growth or growth of polycrystals having orientation.

35. The method for fabricating a semiconductor device according to claim 33 or 34, wherein the thin film is a single crystal or polycrystals having orientation, of SiC, a group III-nitride, or a group II-oxide.

36. The method for fabricating a semiconductor device according to claim 33 or 34, comprising: a step for thinning or flattening the first SiC substrate on the entire surface of the substrate after bonding or fusing, before growing the thin film.

37. The method for fabricating a semiconductor device according to claim 36, wherein as the first SiC substrate, a substrate which is thinned to be equal to or smaller than 50 microns, is utilized.

38. The method for fabricating a semiconductor device according to claim 33 or 34, wherein any one of crystal structures of 3C, 4H, 6H, and 15R is used as the SiC substrate, face orientations of the first crystal face and the second crystal face are the same face orientation, which lies at an angle being equal to or smaller than 15 degrees from {11-20} face or {1-100} face (for 3C; {100}, {110} or {1-10}), and in-plane crystal orientations of the first crystal face and the second crystal face are different from each other by an angle being equal to or greater than 5 degrees.

39. The method for fabricating a semiconductor device according to claim 33 or 34, comprising: a step for growing a thin film on the SiC substrate on which the surface structure is formed, where the first crystal face and the second crystal face exist mixedly, and for subsequently flattening the surface.

40. The method for fabricating a semiconductor device according to claim 39, wherein the thin film is flattened after being grown to an arbitrary thickness being equal to or greater than difference in level existing on the surface of the SiC substrate.

41. The method for fabricating a semiconductor device according to claim 39, wherein the thin film is a single crystal or polycrystals having orientation, of SiC, a group III-nitride, or a group II-oxide.

42. A monolithic device according to claim 18, wherein
both the SiC or the group III-V or II-VI-semiconductor on the first crystal face and the group III-V or II-VI-semiconductor on the second crystal face have thin films formed on the first crystal face and second crystal face of the SiC substrate, respectively, each film inheriting a different feature, by means of epitaxial growth or growth of polycrystals having orientation.

43. The monolithic device according to claim 42, wherein the group III-V or II-VI-semiconductor is formed by both a step for bonding the first SiC substrate and the second SiC substrate so that the rear surface of the first crystal face and the second crystal face are brought into contact with each other, and for completely removing the first SiC substrate at a partial region in the plane thereof, and for exposing the second crystal face being the surface of the second SiC substrate upon the surface of the substrate after bonded, on the surface of the substrate, a structure where the first crystal face of the first SiC substrate and the second crystal face of the second SiC substrate exist mixedly, being formed so that two kinds of crystal faces of the first crystal face and second crystal face appearing on the surface of the substrate are different from each other in at least one of crystal face orientation and in-plane crystal orientation, and a step for growing an arbitrary thin film on a SiC substrate on which a structure have been formed, where the first crystal face and the second crystal face exist mixedly on the surface, and for forming thin films on the first crystal face and the second crystal face of the SiC substrate, respectively, by means of epitaxial growth or growth of polycrystals having orientation, each inheriting different feature of the first crystal face or the second crystal face.

44. The non-linear optical element according to claim 20, wherein
a SiC substrate on which a first crystal face and a second crystal face are formed; and
the first lower clad is formed on the first crystal face by means of epitaxial growth or growth of polycrystals having orientation, the second lower clad is formed on the second crystal face by means of epitaxial growth or growth of polycrystals having orientation.

45. The non-linear optical element according to claim 44, wherein the group III-V or II-VI-semiconductor is formed by both a step for bonding the first SiC substrate and the second SiC substrate so that the rear surface of the first crystal face and the second crystal face are brought into contact with each other, and for completely removing the first SiC substrate at a partial region in the plane thereof, and for exposing the second crystal face being the surface of the second SiC substrate upon the surface of the substrate after bonded, on the surface of the substrate, a structure where the first crystal face of the first SiC substrate and the second crystal face of the second SiC substrate exist mixedly, being formed on the surface so that two kinds of crystal faces of the first crystal face and second crystal face appearing on the surface of the substrate are different from each other in at least one of crystal face orientation and in-plane crystal orientation, and a step for growing an arbitrary thin film on a SiC substrate on which a structure have been formed, where the first crystal face and the second crystal face exist mixedly on the surface, and for forming thin films on the first crystal face and the second crystal face of the SiC substrate, respectively, by means of epitaxial growth or growth of polycrystals having orientation, each inheriting a different feature of the first crystal face or the second crystal face.

46. The non-linear optical element according to claim 45, wherein any one of crystal structures of 3C, 4H, 6H, and 15R is used as the SiC substrate, face orientations of the first crystal face and the second crystal face are the same face orientation, which lies at an angle being equal to or smaller than 15 degrees from {11-20} face or {1-100} face (for 3C; {100}, {110} or {1-10}), and in-plane crystal orientations of the first crystal face and the second crystal face are different from each other by an angle equal to or greater than 5 degrees.

47. The non-linear optical element according to claim 45, comprising: a step for growing a thin film on a SiC substrate on which a surface structure is formed, where the first crystal face and the second crystal face exist mixedly, and for subsequently flattening the surface.

48. The non-linear optical element according to claim 45, wherein the thin film is flattened after being grown to an arbitrary thickness being equal to or greater than the difference in level existing on the surface of the SiC substrate.

49. A semiconductor device comprising: according to claim 21, wherein
the first layer formed on the first crystal face by means of epitaxial growth or growth of polycrystals having orientation and the second layer is formed on the second crystal face by means of epitaxial growth or growth of polycrystals having orientation.

50. The semiconductor device according to claim 49, wherein the group III-V or II-VI-semiconductor is formed by both a step for bonding the first SiC substrate and the second SiC substrate so that the rear surface of the first crystal face and the second crystal face are brought into contact with each other, and for completely removing the first SiC substrate at a partial region in the plane thereof, and for exposing the second crystal face being the surface of the second SiC substrate upon the surface of the substrate after bonded, on the surface of the substrate, a structure where the first crystal face of the first SiC substrate and the second crystal face of the second SiC substrate exist mixedly, being formed so that two kinds of crystal faces of the first crystal face and second crystal face appearing on the surface of the substrate are different from each other in at least one of crystal face orientation and in-plane crystal orientation, and a step for growing an arbitrary thin film on a SiC substrate on which a structure have been formed on the surface, where the first crystal face and the second crystal face exist mixedly, and for forming thin films on the first crystal face and the second crystal face of the SiC substrate, respectively, by means of epitaxial growth or growth of polycrystals having orientation, each inheriting different feature of the first crystal face or the second crystal face.

51. The semiconductor device according to claim 49, wherein the first crystal face is (0001) Si face, and the second crystal face is (000-1) C face.

52. A piezoelectric device, a sensor device, or a micro-machine comprising:
a SiC substrate where a first crystal face and a second crystal face are formed and a high concentration impurity region having a second conductivity-type being different from a first conductivity-type is locally formed in an insulating or first conductivity-type substrate;
a group III-nitride or group II-oxide film on a first layer and a second layer of the SiC substrate, the first layer and the second layer being formed on the first crystal face and the second crystal face, respectively, by means of epitaxial growth or growth of polycrystals having orientation, each inheriting properties of the first crystal face or the second crystal face; and
electrodes being formed both on partial regions of the first substrate and the second substrate, where the film has been removed, and on the III-nitride or group II-oxide film, respectively.

53. The method for fabricating a semiconductor device according to claim 1, further comprising:
a step for growing an arbitrary thin film on a SiC substrate on which a surface structure has been formed, where the first crystal face and the second crystal face exist mixedly on the surface, and for then forming thin films on the first crystal face of the first SiC substrate and the second crystal face of the second SiC substrate, each inheriting a different feature of the first crystal face or the second crystal face by means of epitaxial growth or growth of polycrystals having orientation, wherein
as the SiC substrate, any one of crystal structures of 3C, 4H, 6H, and 15R is used, face orientations of the first crystal face and the second crystal face are the same face orientation, which lies at an angle being equal to or smaller than 15 degrees from non-polar {11-20} face or {1-100} face (for 3C; {100}, {110} or {1-10}), and in-plane crystal orientations of the first crystal face and the second crystal face are different from each other by an angle being equal to or greater than 5 degrees.

54. The method for fabricating a semiconductor device according to claim 2, further comprising:
a step for growing an arbitrary thin film on a SiC substrate on which a surface structure has been formed, where the first crystal face and the second crystal face exist mixedly on the surface, and for then forming thin films on the first crystal face of the first SiC substrate and the second crystal face of the second SiC substrate, each inheriting a different feature of the first crystal face or the second crystal face by means of epitaxial growth or growth of polycrystals having orientation, wherein
as the SiC substrate, any one of crystal structures of 3C, 4H, 6H, and 15R is used, face orientations of the first crystal face and the second crystal face are the same face orientation, which lies at an angle being equal to or smaller than 15 degrees from non-polar {11-20} face or {1-100} face (for 3C; {100}, {110} or {1-10}), and in- plane crystal orientations of the first crystal face and the second crystal face are different from each other by an angle being equal to or greater than 5 degrees.

55. The method for fabricating a semiconductor device according to claim 1, further comprising:
a step for growing an arbitrary thin film on a SiC substrate on which a surface structure has been formed, where the first crystal face and the second crystal face exist mixedly on the surface, and for then forming thin films on the first crystal face of the first SiC substrate and the second crystal face of the second SiC substrate, each inheriting a different feature of the first crystal face or the second crystal face by means of epitaxial growth or growth of polycrystals having orientation; face orientations of the first crystal face and the second crystal face are the same face orientation, or different from each other by an angle being equal to or smaller than 20 degrees, and in-plane crystal orientations thereof are different from each other by an angle being equal to or greater than 10 degrees.

56. The method for fabricating a semiconductor device according to claim 2, further comprising:
a step for growing an arbitrary thin film on a SiC substrate on which a surface structure has been formed, where the first crystal face and the second crystal face exist mixedly on the surface, and for then forming thin films on the first crystal face of the first SiC substrate and the second crystal face of the second SiC substrate, each inheriting a different feature of the first crystal face or the second crystal face by means of epitaxial growth or growth of polycrystals having orientation; face orientations of the first crystal face and the second crystal face are the same face orientation, or different from each other by an angle being equal to or smaller than 20 degrees, and in-plane crystal orientations thereof are different from each other by an angle being equal to or greater than 10 degrees.

57. The method for fabricating a semiconductor device according to any one of claims 53 to 56, comprising: a step for growing a thin film on a SiC substrate on which a surface structure is formed, where the first crystal face and the second crystal face exist mixedly, and for subsequently flattening the surface.

58. The method for fabricating a semiconductor device according to claim 57, wherein the thin film is flattened after being grown to an arbitrary thickness being equal to or greater than difference in level existing on the surface of the SiC substrate.
